(19) United States
(12) Patent Application Publication
(10) Pub. No.: US 2024/0321704 A1
(43) Pub. Date: Sep. 26, 2024

(54) FAN-OUT PACKAGING METHOD AND PACKAGING STRUCTURE OF STACKED CHIPS THEREOF

(71) Applicant: TONGFU MICROELECTRONICS CO., LTD., Nantong (CN)

(72) Inventor: Maohua DU, Nantong (CN)

(21) Appl. No.: 18/680,282

(22) Filed: May 31, 2024

Related U.S. Application Data
(63) Continuation of application No. PCT/CN2022/137248, filed on Dec. 7, 2022.

(30) Foreign Application Priority Data
Dec. 8, 2021 (CN) 202111493814.X
Dec. 8, 2021 (CN) 202111493900.0
Dec. 8, 2021 (CN) 202111493911.9
Dec. 8, 2021 (CN) 202111496036.X
Dec. 8, 2021 (CN) 202111496043.X

(51) Int. Cl. H01L 23/498; H01L 21/603; H01L 23/00; H01L 23/31; H01L 25/065

(52) U.S. Cl. CPC H01L 23/49822; H01L 21/603; H01L 23/3128; H01L 23/49816; H01L 24/08; H01L 24/48; H01L 25/0657; H01L 2224/08145; H01L 2224/08225; H01L 2224/48147; H01L 2224/48227; H01L 2225/06506; H01L 2225/0651; H01L 2924/15172; H01L 2924/15311; H01L 2924/182

(57) ABSTRACT

A fan-out packaging method and packaging structure are provided. The method includes: fixing a first chip in a groove of a dummy chip where the first chip and the dummy chip are provided with a plurality of conductive through holes; bonding the second chip with the dummy chip and the first chip respectively; forming a plastic encapsulation layer to wrap the first chip, the dummy chip and the second chip; and forming a redistribution wiring layer on surfaces of the dummy chip and the first chip away from the second chip. The redistribution layer is electrically connected to the first chip through the plurality of conductive through holes.

### CROSS-REFERENCE TO RELATED APPLICATION

This application is a continuation application of International Application No. PCT/CN2022/137248, filed on Dec. 7, 2022, which claims the priority of Chinese Patent Application No. 202111496036.X, filed on Dec. 8, 2021, Chinese Patent Application No. 202111496043.X, filed on Dec. 8, 2021, Chinese Patent Application No. 202111493900.0, filed on Dec. 8, 2021, Chinese Patent Application No. 202111493911.9, filed on Dec. 8, 2021, Chinese Patent Application No. 202111493814.X, filed on Dec. 8, 2021, the contents of all of which are incorporated herein by reference in their entirety.

### TECHNICAL FIELD

The present disclosure generally relates to the field of semiconductor packaging technology and, more particularly, relates to a fan-out packaging method and a packaging structure of stacked chips.

### BACKGROUND

Size of an electronic product is getting smaller and smaller, and their functions are getting stronger. Subsequently, semiconductor packages are required to be thinner and thinner, and interconnection density becomes higher. Traditional packaging cannot meet future demands. FIG. 1 shows a typical existing multilayer chip packaging structure. A chip 1 and a chip 2 are vertically stacked on a substrate 6 through patch films 3 and 4, and the chips 1 and 2 are connected to the substrate 6 through gold wires 5. The chips 1 and 2, and the gold wire 5 are protected by plastic encapsulant 7. The entire package is connected to the outside world through solder balls 8. In existing packaging structures, because of limitation of a height of molding of a gold wire and limitation of a protection distance from the plastic encapsulant to the gold wire, a height from the plastic encapsulant to a surface of the chip 2 is strictly limited and cannot be continuously reduced. At the same time, production of an ultra-thin substrate is extremely difficult because of limitations of substrate materials and substrate strength, which limit the application of existing packaging in ultra-thin multi-layer packaging. Moreover, for a traditional wire bonding connection or a reverse soldering connection, a pad spacing is above 30 μm, and it is extremely difficult to continue shrinking.

Therefore, it is necessary to provide a fan-out packaging method and packaging structure of stacked chips that could effectively solve the above problems.

### SUMMARY

One aspect of the present disclosure provides a fan-out packaging method. The method includes: fixing a first chip in a groove of a dummy chip where the first chip and the dummy chip are provided with a plurality of conductive through holes; bonding the second chip with the dummy chip and the first chip respectively; forming a plastic encapsulation layer to wrap the first chip, the dummy chip and the second chip; and forming a redistribution wiring layer on surfaces of the dummy chip and the first chip away from the second chip. The redistribution layer is electrically connected to the first chip through the plurality of conductive through holes.

Another aspect of the present disclosure provides a fan-out packaging structure. The structure includes a dummy chip, a first chip, a second chip, a bonding structure, a plastic encapsulation layer, and a redistribution wiring layer. The dummy chip includes a groove and the first chip is disposed in the groove. The first chip and the dummy chip are both provided with a plurality of conductive through holes. The second chip is stacked on the first chip and the dummy chip. The second chip is bonded and connected to the dummy chip and the first chip respectively through the bonding structure. The plastic encapsulation layer wraps the first chip, the dummy chip, and the second chip. The redistribution wiring layer is disposed on surfaces of the dummy chip and the first chip away from the second chip, and is electrically connected to the first chip through the plurality of conductive through holes.

### BRIEF DESCRIPTION OF THE DRAWINGS

The following drawings are merely examples for illustrative purposes according to various disclosed embodiments and are not intended to limit the scope of the present disclosure.

FIG. 1 illustrates a multilayer chip packaging method.

FIG. 2 illustrates an exemplary fan-out stacked chip packaging method according to various disclosed embodiments of the present disclosure.

FIG. 3 to FIG. 11 illustrate structures corresponding to certain stages of a fan-out stacked chip packaging method according to various disclosed embodiments of the present disclosure.

FIG. 12 illustrates an exemplary fan-out stacked chip packaging method according to various disclosed embodiments of the present disclosure.

FIG. 13 to FIG. 27 illustrate structures corresponding to certain stages of a fan-out stacked chip packaging method according to various disclosed embodiments of the present disclosure.

FIG. 28 illustrates an exemplary fan-out stacked chip packaging method according to various disclosed embodiments of the present disclosure.

FIG. 29 to FIG. 37 illustrate structures corresponding to certain stages of a fan-out stacked chip packaging method according to various disclosed embodiments of the present disclosure.

FIG. 38 illustrates an exemplary fan-out stacked chip packaging method according to various disclosed embodiments of the present disclosure.

FIG. 39 to FIG. 48 illustrate structures corresponding to certain stages of a fan-out stacked chip packaging method according to various disclosed embodiments of the present disclosure.

FIG. 49 illustrates an exemplary fan-out stacked chip packaging method according to various disclosed embodiments of the present disclosure.

FIG. 50 to FIG. 59 illustrate structures corresponding to certain stages of a fan-out stacked chip packaging method according to various disclosed embodiments of the present disclosure.

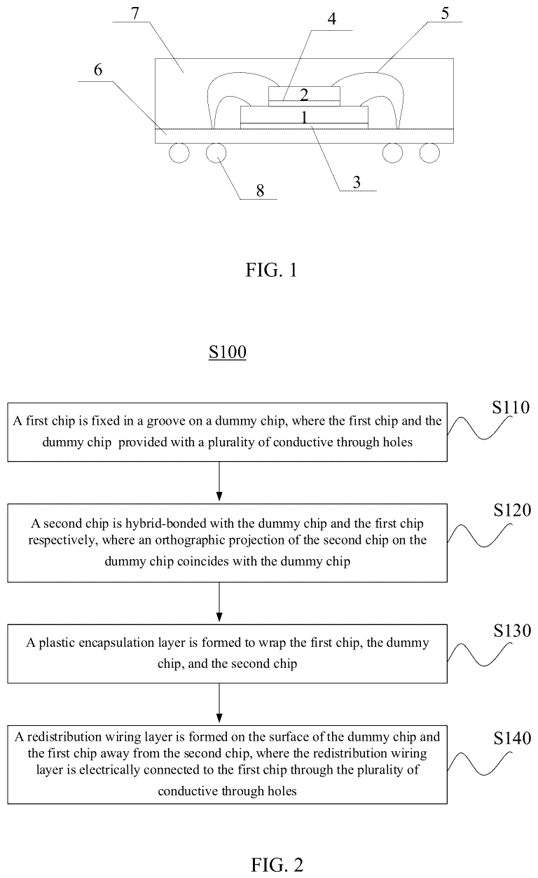

### DETAILED DESCRIPTION

Reference will now be made in detail to exemplary embodiments of the disclosure, which are illustrated in the accompanying drawings. Wherever possible, the same reference numbers will be used throughout the drawings to refer to the same or like parts.

It should be noted that “surface” or “upper” in this specification are used to describe the relative positional relationship in space, and are not limited to whether they are in direct contact.

The present disclosure provides a fan-out stacked chip packaging method.

As shown in FIG. 2, one embodiment of the present disclosure provides a fan-out stacked chip packaging method S100. The packaging method of S100 may include S110 to S140.

In S110, a first chip may be fixed in a groove on a dummy chip. The first chip and the dummy chip may be provided with a plurality of conductive through holes.

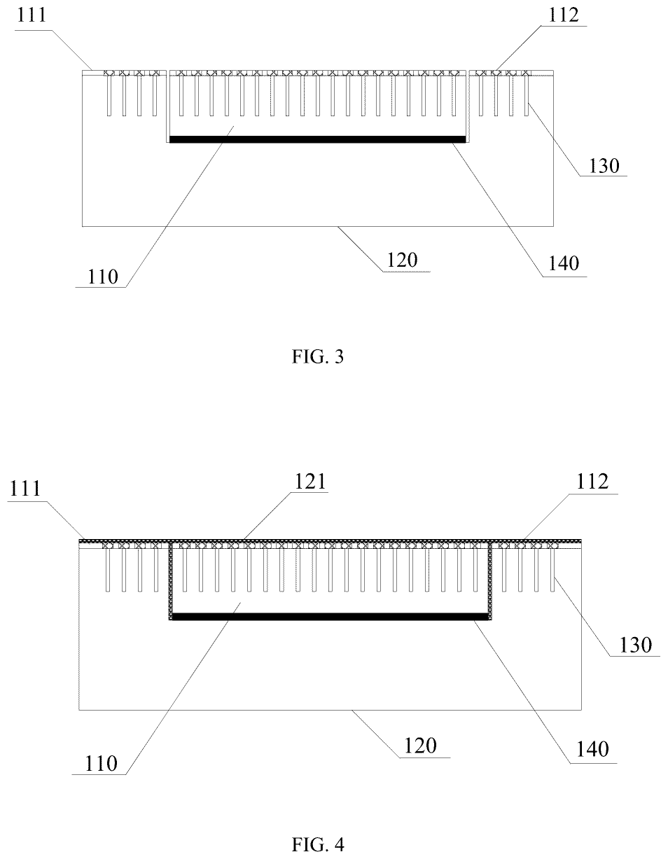

Specifically, as shown in FIG. 3, a back side of the first chip 110 may be fixed in the groove on the dummy chip 120 by patch adhesive 140, and a surface of the first chip 110 may be flush with a surface of the dummy chip 120. The plurality of conductive through holes 130 may be disposed on a front surface of the first chip 110 and a front surface of the dummy chip 120, and the plurality of conductive through holes 130 may be distributed at equal intervals. The plurality of conductive through holes 130 may be through-silicon vias. The through-silicon vias may be used to realize vertical electrical interconnection of through-silicon vias. The package height may be reduced. Signals of the first chip 110 and a second chip 150 may be connected to the outside through the plurality of conductive holes 130.

In S120, the second chip may be hybrid-bonded with the dummy chip and the first chip respectively. An orthographic projection of the second chip on the dummy chip may coincide with the dummy chip.

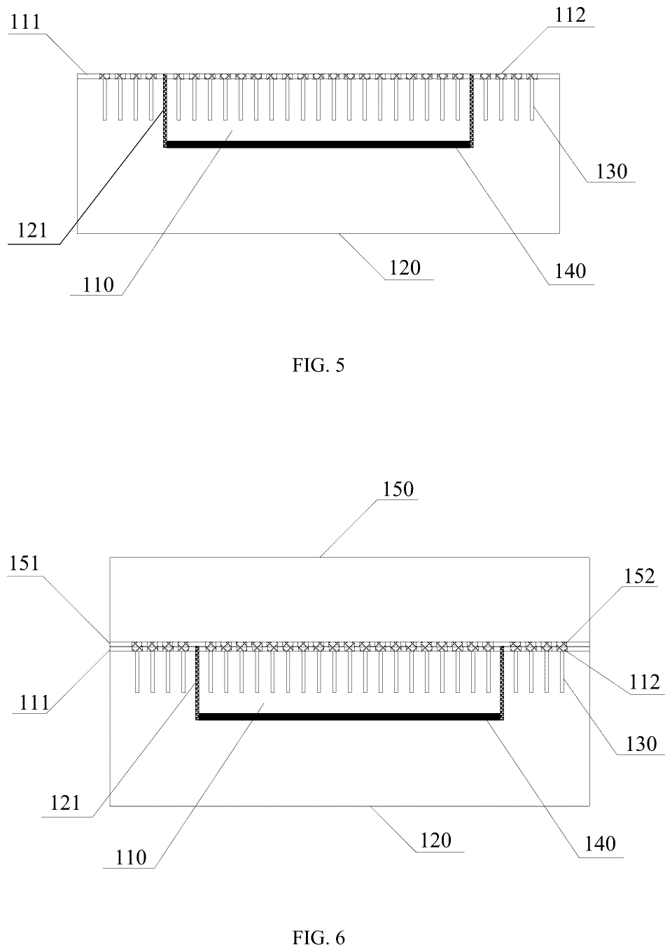

Specifically, as shown in FIG. 3, FIG. 4 and FIG. 5, a surface of the first chip 110 and a surface of the dummy chip 120 facing the second chip 150 may be provided with a first passivation layer 111 and first metal pads 112. Each first metal pad 112 on the first chip 110 may correspond to one of the plurality of conductive through holes 130 of the first chip 110, and each first metal pad 112 on the dummy chip 120 may correspond to one of the plurality of conductive through holes 130 of the dummy chip 120. As shown in FIG. 6, a surface of the second chip 150 facing the first chip 110 may be provided with a second passivation layer 151 and second metal pads 152.

The second chip may be hybrid-bonded with the dummy chip and the first chip respectively by following processes.

First, the first passivation layer 111 of the first chip 110 and the dummy chip 120 may be bonded with the second passivation layer 151 of the second chip 150. In one embodiment, the first passivation layer 111 and the second passivation layer 151 may be made of a material including a silicon dioxide layer, a silicon nitride layer, or other materials that play a passivation role, which is not limited in the present disclosure. Specifically, the first passivation layer 111 and the second passivation layer 151 may be aligned first. Then, the first passivation layer 111 may be connected to the second passivation layer 151 through high-temperature pressure bonding.

Subsequently, the first metal pads 112 of the first chip 110 and the dummy chip 120 and the second metal pads 152 of the second chip 150 may be bonded. In one embodiment, the first metal pads 112 and the second metal pads 152 may be made of a material including metal copper (that is, copper pads), or other metal materials, which are not specifically limited in this embodiment. Specifically, the first metal pads 112 may be aligned with the second metal pads 152, and the connection may be realized through high-temperature compression and thermal expansion of copper.

As shown in FIG. 6, the orthographic projection of the second chip 150 on the dummy chip 120 may coincide with the dummy chip 120. That is, the size of the second chip 150 may be consistent with the size of the dummy chip 120. The first chip 110 and the second chip 150 of two different sizes may be adjusted to the same size by using a dummy chip to expand the functional area of the first chip 110. The first chip and the second chip of two different sizes may be adjusted to the same size through wafer expansion technology, and then wafer-level hybrid bonding may be performed to achieve high-density interconnection while improving production efficiency.

In one embodiment, before hybrid bonding the second chip with the dummy chip and the first chip respectively, the method may further include: first, forming an adhesive on the surfaces of the dummy chip and the first chip, where a portion of the adhesive may be filled into a gap between the dummy chip and the first chip; and then removing the adhesive on the surface of the dummy chip and the first chip to expose the first passivation layer and the first metal pads of the dummy chip and the first chip.

Specifically, as shown in FIG. 4, the adhesive 121 may be formed on the surfaces of the dummy chip 120 and the first chip 110, and a portion of the adhesive 121 may be filled into the gap between the dummy chip 120 and the first chip 110. The first chip 110 may be completely fixed in the groove of the dummy chip 120.

Specifically, the surface of the adhesive 121 may be ground and polished to remove the adhesive 121 on the surfaces of the dummy chip 120 and the first chip 110, as shown in FIG. 5, to expose the first passivation layer 111 and the first metal pads 112 of the dummy chip 120 and the first chip 110. In some other embodiments, other methods may also be used to remove the adhesive 121, which is not specifically limited in the present disclosure.

The interconnection density of hybrid bonding is high and bonding with a spacing of less than 1 um may be realized, which may improve production efficiency while achieving high-density interconnection.

In S130, a plastic encapsulation layer may be formed to wrap the first chip, the dummy chip, and the second chip.

First, the bonded first chip and the dummy chip may be thinned to expose the plurality of conductive through holes of the first chip and the dummy chip.

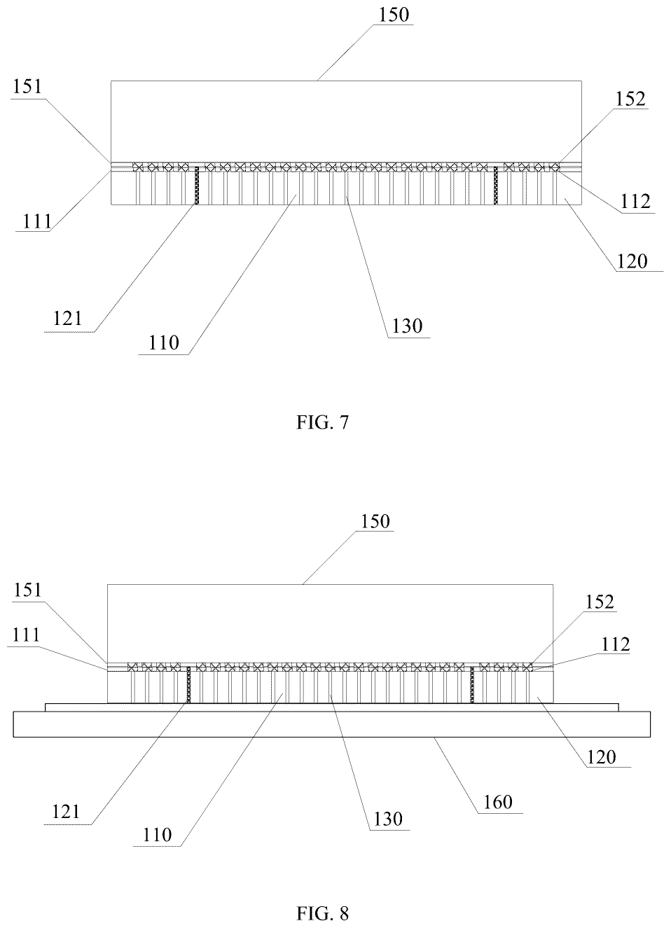

Specifically, as shown in FIG. 7, the backsides of the bonded first chip 110 and the dummy chip 120 may be thinned to expose the plurality of conductive through holes 130 of the first chip 110 and the dummy chip 120, that is, the through-silicon vias. A residual thickness of the first chip 110 and the dummy chip 120 after thinning may be less than 40 μm. By thinning the backsides of the first chip 110 and the dummy chip 120, the plurality of conductive through holes 130 may be exposed for electrical connection, further reducing the package height.

Subsequently, the surface of the thinned first chip and the dummy chip facing away from the second chip may be fixed on a temporary carrier, and then the plastic encapsulation layer may be formed.

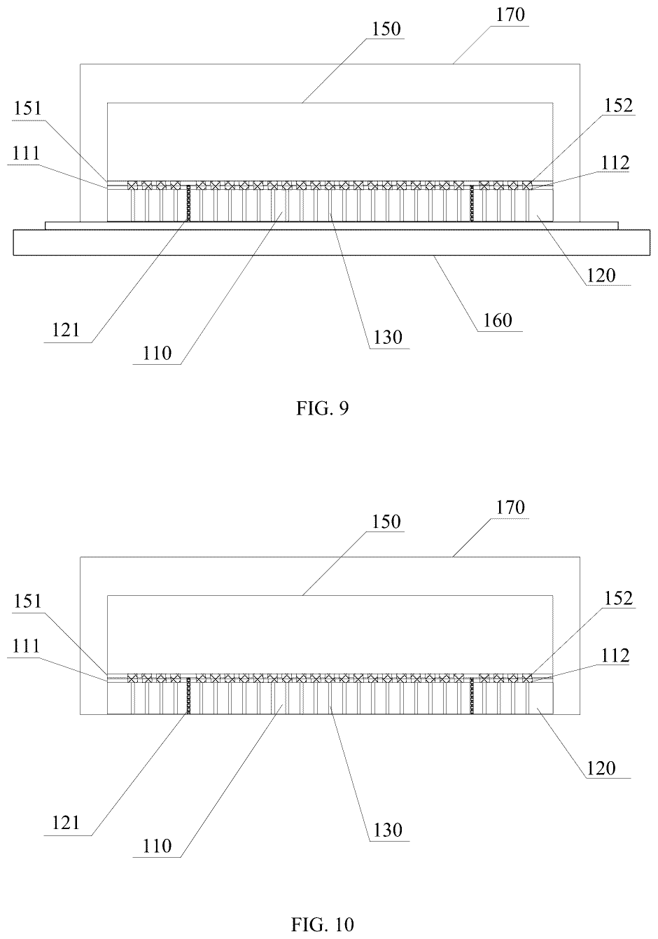

Specifically, the above packaging process may be used to package a plurality of first chips 110, a plurality of dummy chips 120 and a plurality of second chips 150 at the same time. After thinning, a plurality of chip assemblies may be cut to form a plurality of independent chip assemblies shown in FIG. 7 and then the following packaging process may be performed on each of the plurality of independent chip assemblies. As shown in FIG. 8, the surface of the thinned first chip 110 and dummy chip 120 away from the second chip 150 may be fixed on the temporary carrier 160. That is, the backsides of the first chip 110 and the dummy chip 120 may be used as a contact surface. According to the final packaging size, they may be attached to the temporary carrier 160 with temporary bonding glue one by one, and then packaged to form the plastic encapsulation layer 170 as shown in FIG. 9. The plastic encapsulation layer 170 may wrap the first Chip 110, the dummy chip 120, and second chip 150. The plastic encapsulation layer may be formed by a plastic encapsulation method including film vacuum lamination or traditional plastic sealing process, which is not specifically limited in the present disclosure.

In S140, a redistribution wiring layer may be formed on the surface of the dummy chip and the first chip away from the second chip, and the redistribution wiring layer may be electrically connected to the first chip through the plurality of conductive through holes.

In one embodiment, the redistribution wiring layer may be formed on the surface of the dummy chip and the first chip away from the second chip by: separating the first chip and the dummy chip from the temporary carrier; forming a dielectric layer on surfaces of the plastic encapsulation layer, the dummy chip and the first chip away from the second chip; and patterning the dielectric layer and forming the redistribution wiring layer on the patterned dielectric layer.

Specifically, as shown in FIG. 10, the first chip 110 and the dummy chip 120 may be separated from the temporary carrier 160. That is, the temporary carrier 160 may be removed. The first chip 110 and the dummy chip 120 may be separated from the temporary carrier 160 by a separation method including thermal separation, laser separation, ultraviolet light separation, mechanical separation or other methods. These methods are currently commonly used temporary bonding separation methods. The separation method is not specifically limited in the present disclosure, and may be selected according to actual needs.

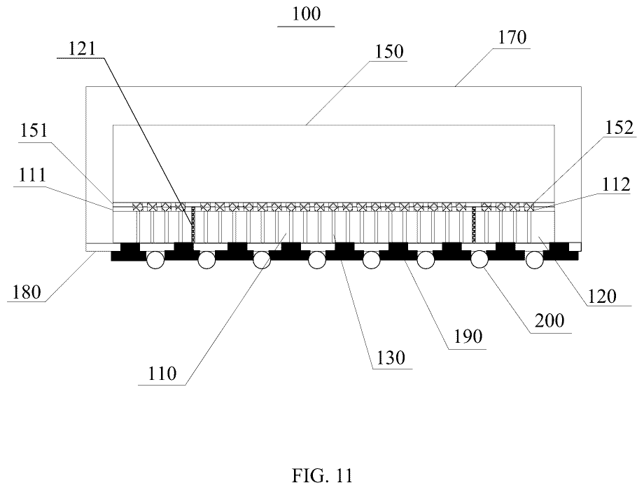

As shown in FIG. 11, the dielectric layer 180 may be coated on the surfaces of the plastic encapsulation layer 170, the dummy chip 120 and the first chip 110 away from the second chip 150. That is, the dielectric layer 180 may be formed on the backside of the plastic encapsulation layer 170, the thinned first chip 110 and the dummy chip 120. The dielectric layer 180 may be made of a material including polyimide (PI), polybenzoxazole (PBO), etc., and may be formed by a coating method including wafer spin coating, which are not specifically limited in the present disclosure.

As shown in FIG. 11, the dielectric layer 180 may be patterned by a photolithography process, and the redistribution wiring layer 190 may be formed on the patterned dielectric layer 180. The redistribution wiring layer 190 may be electrically connected to the first chip 110 through the plurality of conductive through holes 130. The redistribution wiring layer 190 may be formed by a method including electroplating, sputtering, thermal evaporation, plasma enhanced chemical vapor deposition, low pressure chemical vapor deposition, atmospheric pressure chemical vapor deposition, or electron cyclotron resonance chemical vapor deposition, etc., which is not specifically limited in the present disclosure. The redistribution wiring layer 190 may be made of a material including metal titanium or metal copper, which is not limited in the present disclosure.

Subsequently, the redistribution wiring layer may be patterned, and solder balls may be formed on the patterned redistribution wiring layer.

Specifically, as shown in FIG. 11, the redistribution wiring layer 190 may be patterned by a photolithography process, and ball planting may be performed on the patterned redistribution wiring layer 190 to form a plurality of solder balls 200. Electrically connection to the outside world may be realized through the plurality of solder balls 200.

In the fan-out stacked chip packaging method provided by the present disclosure, the first chip may be fixed in the groove on the dummy chip, and both the first chip and the dummy chip may be provided with the plurality of conductive through holes. The second chip may be hybrid-bonded to the dummy chip and the first chip respectively, through wafer expansion technology, and then the wafer-level hybrid bonding may be performed to achieve high-density interconnection while improving production efficiency. Also, conductive through hole technology and fan-out rewiring technology may be used to replace existing substrate interconnection, to reduce package size. Further, since the first chip and the second chip may be directly bonded through wafer bonding, the thickness after bonding may be the same as that of the chip body, which minimizes the package height and achieves ultra-thinning multilayer high-density stacked packaging.

The present disclosure also provides a fan-out stacked chip packaging structure. As shown in FIG. 11, in one embodiment, the fan-out stacked chip packaging structure 100 may include a dummy chip 120, a first chip 110, a second chip 150, a hybrid bonding structure (not shown in the figure), a plastic encapsulation layer 170, and a redistribution wiring layer 180. The dummy chip 120 may be provided with a groove, and the first chip 110 may be disposed in the groove. The first chip 110 and the dummy chip 120 may be both provided with a plurality of conductive through holes 130, and the plurality of conductive through holes 130 may be through-silicon vias. The through-silicon vias may be used to realize the vertical electrical interconnection, which reduces the package height.

The second chip 150 may be stacked on the first chip 110 and the dummy chip 120. The second chip 150 may be connected to the dummy chip 120 and the first chip 110 by hybrid bonding respectively. An orthographic projection of the second chip on the dummy chip 120 may coincide with the dummy chip 120. That is, the size of the second chip 150 may be the same as that of the dummy chip 120. The first chip 110 and the second chip 150 of two different sizes may be adjusted to the same size by the dummy chip 120, thereby expanding the function area of the first chip 110.

The plastic encapsulation layer 170 may wrap the first chip 110, the dummy chip 120 and the second chip 150 to protect the first chip 110, the dummy chip 120 and the second chip 150.

The redistribution wiring layer 190 may be disposed on the surfaces of the dummy chip 120 and the first chip 110 away from the second chip 150, and may be electrically connected to the first chip 110 through the plurality of conductive through holes 130. The redistribution wiring layer 190 may be formed by a method including electroplating, sputtering, thermal evaporation, plasma enhanced chemical vapor deposition, low pressure chemical vapor deposition, atmospheric pressure chemical vapor deposition, or electron cyclotron resonance chemical vapor deposition, etc., which is not specifically limited in the present disclosure. The redistribution wiring layer 190 may be made of a material including metal titanium or metal copper, which is not limited in the present disclosure. The packaging structure 100 may use the plurality of through holes 130 and the redistribution wiring layer 190 to lead out the signals of the first chip 110 and the second chip 150.

In one embodiment shown in FIG. 11, the hybrid bonding structure may include a first passivation layer 111 and first metal pads 112 disposed on the surfaces of the first chip 110 and the dummy chip 120 facing the second chip 150, and a second passivation layer 151 and second metal pads 152 on a surface of the second chip 150 facing the first chip 110. The first passivation layer 111 and the second passivation layer 151 may be bonded and connected, and the first metal pads 112 and the second metal pads 152 may be bonded. The interconnection density of hybrid bonding may be high, and bonding with a spacing of less than 1 μm may be realized, which may improve production efficiency while achieving high-density interconnection

In one embodiment shown in FIG. 11, the surface of the first chip 110 may be flush with the surface of the dummy chip 120.

In one embodiment shown in FIG. 11, the packaging structure 100 may further include a dielectric layer 180 and solder balls 200. The dielectric layer 180 may be disposed on the surfaces of the plastic encapsulation layer 170, the dummy chip 120 and the first chip 110 away from the second chip 150. The redistribution wiring layer 190 may be disposed on the dielectric layer 180 and the solder balls 200 may be disposed on the redistribution wiring layer 190. The solder balls 200 may be electrically connected to the outside.

In the fan-out stacked chip packaging structure provided by the present disclosure, the first chip and the second chip of two different sizes may be adjusted to the same size by fixing the first chip in the groove of the dummy chip, and the second chip may be stacked and disposed on the first chip and the dummy chip. The second chip may be respectively connected to the dummy chip and the first chip through a hybrid bonding structure, realizing high-density interconnection while improving production efficiency. The packaging height may be reduced to the greatest extent, realizing ultra-thin packaging.

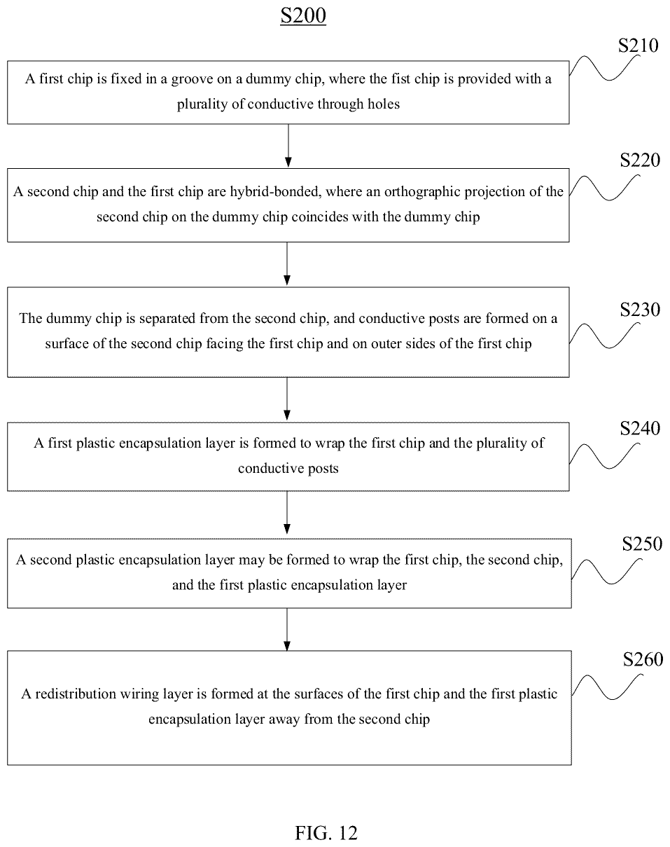

Another embodiment of the present disclosure provides another fan-out stacked chip packaging method S200. As shown in FIG. 12, the method S200 may include S210 to S260.

In S210, a first chip may be fixed in a groove on a dummy chip. The first chip may be provided with a plurality of conductive through holes.

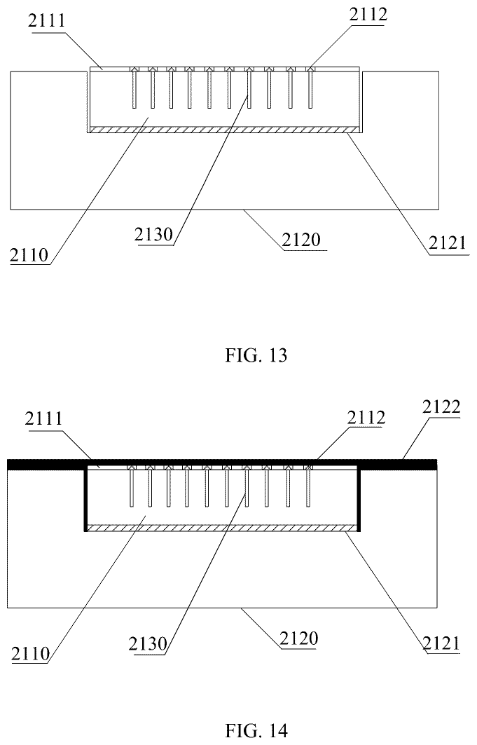

Specifically, as shown in FIG. 13, a back side of the first chip 2110 may be fixed in the groove on the dummy chip 2120 by adhesive 2121. The surface of the first chip 2110 may protrude out from the surface of the dummy chip 2120. The front surface of the first chip 2110 may be provided with the plurality of conductive through holes 2130, and the plurality of conductive through holes 2130 may be distributed at equal intervals. The plurality of conductive through holes may be through-silicon vias. Through-silicon via technology may be used to realize the vertical electrical interconnection of through-silicon vias, which may reduce the package height.

As shown in FIG. 13, a first passivation layer 2111 and first metal pad 2112 may be disposed on a surface of the first chip 2110 away from the groove. The first passivation layer 2111 may be made of a material including a silicon dioxide passivation layer, a silicon nitride passivation layer, or other materials that can play a passivation role, which is not specifically limited in the present disclosure. The first metal pads 2112 may be made of a material including metal copper or other metal materials, which is not specifically limited in the present disclosure.

In S220, a second chip and the first chip may be hybrid-bonded. An orthographic projection of the second chip on the dummy chip may coincide with the dummy chip.

In one embodiment, before hybrid bonding the second chip with the dummy chip and the first chip respectively, the method may further include: first, forming an adhesive on first surfaces of the dummy chip and the first chip, where a portion of the adhesive may be filled into a gap between the dummy chip and the first chip; and then completely removing a portion of the adhesive on the first surface of the first chip and preserving another portion of the adhesive on the surface of the dummy chip, to expose the first passivation layer and the first metal pads on the first chip.

Specifically, as shown in FIG. 14, the adhesive 2122 may be formed on the first surfaces of the dummy chip 2120 and the first chip 2110, and a portion of the adhesive 2121 may be filled into the gap between the dummy chip 2120 and the first chip 2110. The first chip 2110 may be completely fixed in the groove of the dummy chip 2120. Since the first surface of the first chip 2110 protrudes from the surface of the dummy chip 2120, the adhesive 2122 on the dummy chip 2120 may be thicker than the adhesive glue 2122 on the first surface of the first chip 2110. When hybrid bonding is performed between the first chip 2110 and the second chip 2140, the second chip 2140 may be fixed on the dummy sheet 2120.

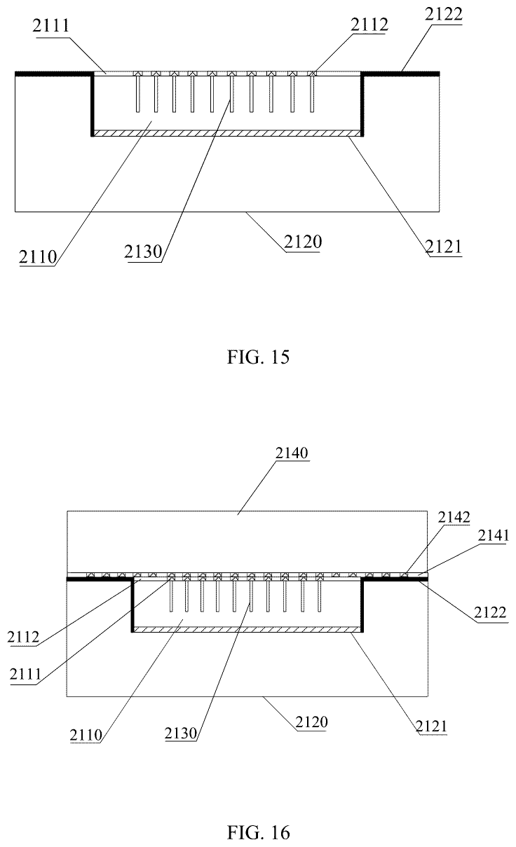

Specifically, the surface of the adhesive 2122 on the first surface of the first chip 2110 may be ground and polished to completely remove the adhesive 2122 on the first surface of the first chip 2110 and preserve the adhesive 2122 on the first surface of the dummy chip 2120, as shown in FIG. 15, to expose the first passivation layer 2111 and the first metal pads 2112 on the first chip 110. The portion of the adhesive 2122 on the surface of the dummy chip 2120 may be used to fix the dummy chip 2120 on the second chip 2140.

As shown in FIG. 16, the first passivation layer 2111 and the first metal pads 2112 may be disposed on a surface of the first chip 2110 facing the second chip 2140. That is, the first passivation layer 2111 and the first metal pads 2112 may be disposed on the surface of the first chip 2110 away from the groove. Each first metal pad 2112 on the first chip 2110 may correspond to one of the plurality of conductive through holes 2130 of the first chip 2110. A second passivation layer 2141 and second metal pads 2142 may be disposed on a surface of the second chip 2140 facing the first chip 2110.

In one embodiment, the second chip may be hybrid-bonded with the first chip by following processes.

First, the first passivation layer of the first chip may be bonded with the second passivation layer of the second chip.

Specifically, as shown in FIG. 16, the first passivation layer 2111 of the first chip 2110 may be bonded with the second passivation layer 2141 of the second chip 2140. In one embodiment, the first passivation layer 2111 and the second passivation layer 2141 may be made of a material including a silicon dioxide layer, a silicon nitride layer, or other materials that play a passivation role, which is not limited in the present disclosure. Specifically, the first passivation layer 2111 and the second passivation layer 2141 may be aligned first. Then, the first passivation layer 2111 may be connected to the second passivation layer 2141 through high temperature pressure bonding.

Subsequently, the first metal pads of the first chip may be bonded with the second metal pads of the second chip.

Specifically, as shown in FIG. 16, the first metal pads 2112 of the first chip 2110 and the second metal pads 2142 of the second chip 2140 may be bonded. In one embodiment, the first metal pads 112 and the second metal pads 2142 may be made of a material including metal copper (that is, copper pads), or other metal materials, which are not specifically limited in this embodiment. Specifically, the first metal pads 2112 may be aligned with the second metal pads 2142, and the connection may be realized through high-temperature compression and thermal expansion of copper.

As shown in FIG. 16, the orthographic projection of the second chip 2140 on the dummy chip 2120 may coincide with the dummy chip 2120. That is, the size of the second chip 2140 may be consistent with the size of the dummy chip 2120. The first chip 2110 and the second chip 2140 of two different sizes may be adjusted to the same size by using a dummy chip to expand the functional area of the first chip 2110. The first chip and the second chip of two different sizes may be adjusted to the same size through wafer expansion technology, and then wafer-level hybrid bonding may be performed to achieve high-density interconnection while improving production efficiency.

In S2130, the dummy chip may be separated from the second chip, and a plurality of conductive posts may be formed on a surface of the second chip facing the first chip and on outer sides of the first chip.

In one embodiment, before separating the dummy chip from the second chip, the method may further include thinning the first chip and the dummy chip after bonding to expose the plurality of conductive through holes of the first chip.

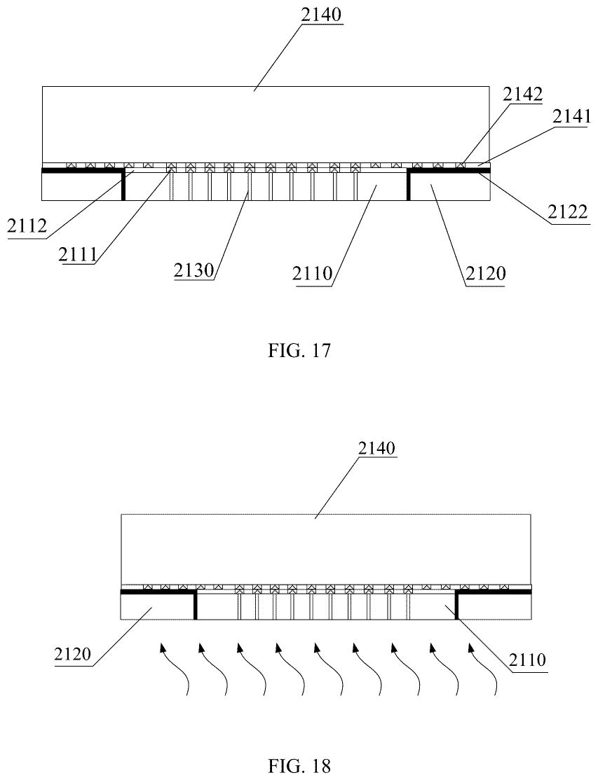

Specifically, as shown in FIG. 17, backsides of the bonded first chip 2110 and the dummy chip 2120 may be thinned to expose the plurality of conductive through holes 2130 on the first chip 2110, that is, to expose the silicon through silicon holes. The residual thickness of the first chip 2110 and the dummy chip 2120 after thinning may be less than 40 μm. By thinning the backsides of the first chip 2110 and the dummy chip 2120, the plurality of conductive through holes 2130 may be exposed for electrical connection, further reducing the package height.

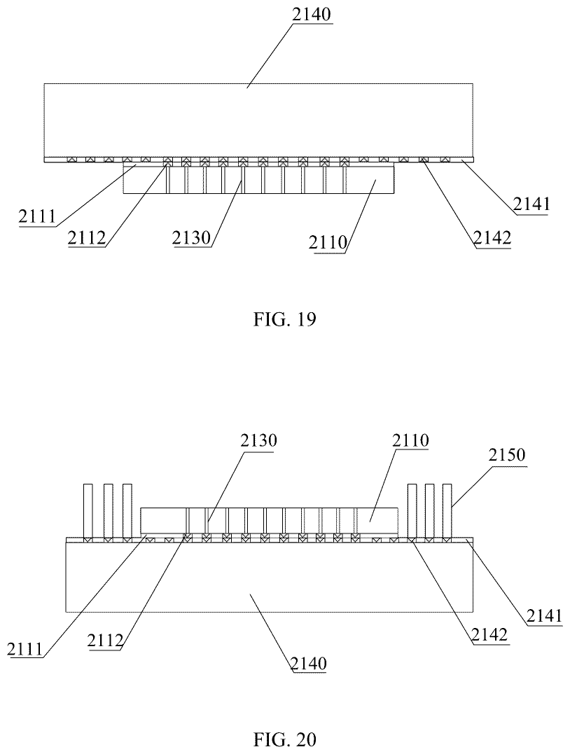

As shown in FIG. 18, the first chip 2110 and the dummy chip 2120 may be irradiated with laser or ultraviolet light, where the light wave is determined according to the characteristics of the adhesive 2122. Under the action of light wave energy, the adhesive 2122 may lose its viscosity. Correspondingly, as shown in FIG. 19, the dummy chip 2120 may be detached from the second chip 2140, that is, the second chip 2140 may be separated from the dummy chip 2120, leaving the hybrid-bonded first chip 2110 and the second chip 2140. It should be noted that other methods may also be used to separate the second chip 2140 from the dummy chip 2120, which is not specifically limited in this embodiment.

As shown in FIG. 20, after the second chip 2140 is separated from the dummy chip 2120, the plurality of conductive posts 2150 may be formed on the surface of the second chip 2140 facing the first chip 2110 and on the outer side of the first chip 2110 by electroplating or other processes. That is, the plurality of conductive posts 2150 may be disposed at the position of the dummy chip 2120 before the second chip 2140 is separated from the dummy chip 2120. The plurality of conductive posts 2150 may be plated on the second metal pads 2142. A portion of signals of the second chip 2140 may be led out by the plurality of conductive posts 2150. Compared with the substrate interconnection, the vertical electrical interconnection in the present embodiment may be realized by using the plurality of conductive posts 2150, which may reduce the packaging height.

In this embodiment, the plurality of conductive posts 2150 may be metal copper posts. In other embodiments, the plurality of conductive posts 2150 may be made of other metal materials.

In S240, a first plastic encapsulation layer is formed to wrap the first chip and the plurality of conductive posts.

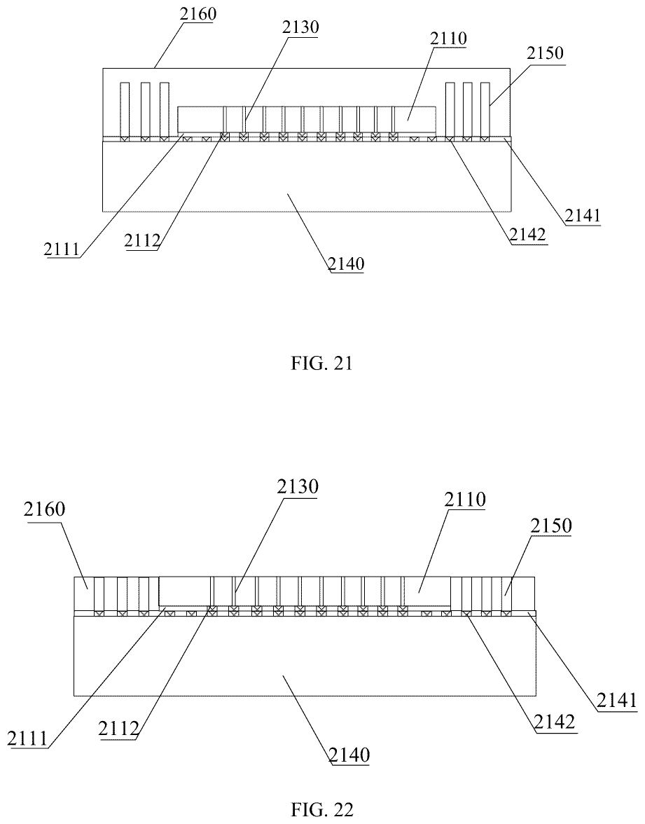

Specifically, as shown in FIG. 21, after forming the plurality of conductive posts 2150, the first plastic encapsulation layer 2160 may be formed at a side of the first chip 2110 away from the second chip 2140. The first plastic encapsulation layer 2160 may wrap the plurality of conductive posts 2150 and the first chip 2110. The first plastic encapsulation layer 2160 may protect the plurality of conductive posts 2150 and the first chip 2110. The first plastic encapsulation layer 2160 may be formed by a plastic encapsulation method including film vacuum lamination or traditional plastic sealing process, which is not specifically limited in this embodiment.

In S250, a second plastic encapsulation layer may be formed to wrap the first chip, the second chip, and the first plastic encapsulation layer.

First, a side of the first plastic encapsulation layer away from the second chip may be thinned, to expose the plurality of conductive posts, such that the first plastic encapsulation layer is flush with a second surface of the first chip.

Specifically, as shown in FIG. 21, the side of the first plastic encapsulation layer 2160 facing away from the second chip 2140 may be thinned by grinding, polishing or chemical cleaning to expose the plurality of conductive posts 2150 and the plurality of conductive through holes 2130, such that the first plastic encapsulation layer 2160 may be flush with the second surface of the thinned first chip 2110, that is, the first plastic encapsulation layer 2160 may be flush with the back surface of the thinned first chip 2110.

Subsequently, the thinned first plastic encapsulation layer and the second surface of the first chip may be fixed on a temporary carrier, and then the second plastic encapsulation layer may be formed.

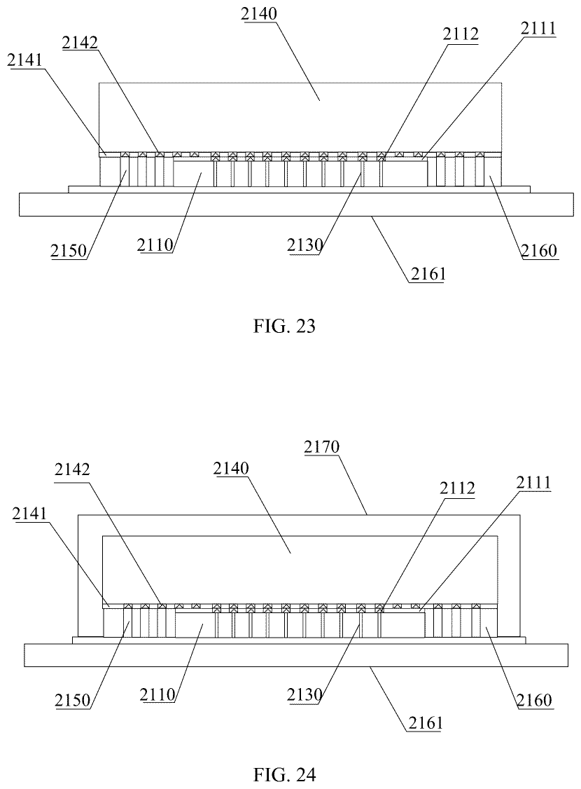

The above packaging process may be performed on multiple first chips 2110, multiple dummy chips 2120 and multiple second chips 2140 at the same time. The thinned multiple chip assemblies may be cut to form multiple independent chip assemblies as shown in FIG. 22, after thinning the side of the first plastic encapsulation layer 2160 away from the second chip 2140. Subsequent processes may be performed then. As shown in FIG. 23, the surfaces of the thinned first plastic encapsulation layer 2160 and the first chip 2110 away from the second chip 2140 may be fixed on the temporary carrier 161 by adhesive. That is, using the back side of the first chip 2110 as the contact surface and according to the final packaging size, they may be bonded to the temporary carrier 161 with temporary bonding glue one by one, and then plastic encapsulation may be performed, to form the second plastic encapsulation layer 2170 as shown in FIG. 24. The second plastic encapsulation layer 2170 may wrap the first chip 2110, the second chip 2140 and the first plastic encapsulation layer 2160. The plastic encapsulation may be film vacuum lamination or traditional plastic sealing process, which is not specifically limited in this embodiment.

In S260, a redistribution wiring layer may be formed at the surfaces of the first chip and the first plastic encapsulation layer away from the second chip. The redistribution wiring layer may be electrically connected to the first chip through the plurality of conductive through holes, and may be electrically connected to the second chip through the plurality of conductive posts.

In one embodiment, the redistribution wiring layer may be formed on the surfaces of the first chip and the first plastic encapsulation layer away from the second chip by the following processes.

Firstly, the first chip and the first plastic encapsulation layer may be separated from the temporary carrier.

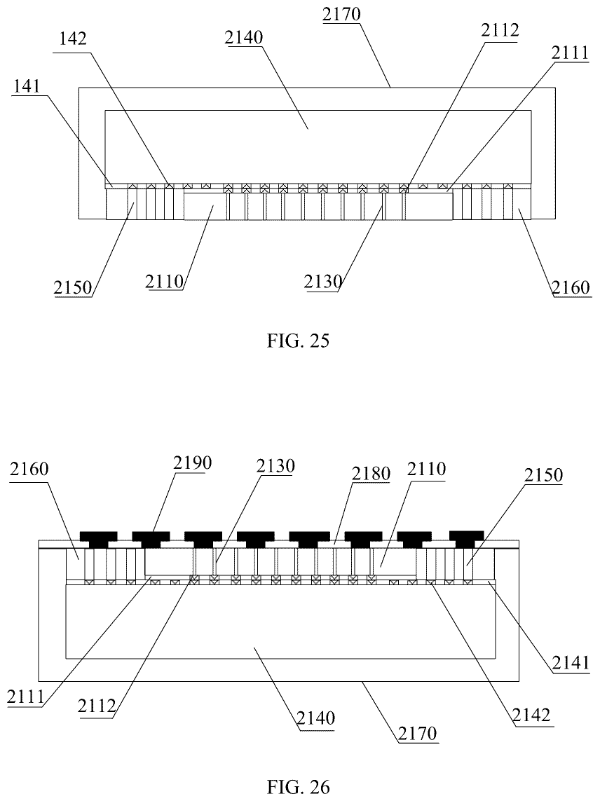

Specifically, as shown in FIG. 25, the first chip 2110 and the first plastic encapsulation layer 2160 may be separated from the temporary carrier 2161. That is, the temporary carrier 2161 may be removed. The first chip 2110 and the first plastic encapsulation layer 2160 may be separated from the temporary carrier 2161 by a separation method including thermal separation, laser separation, ultraviolet light separation, mechanical separation and other methods. These methods are currently commonly used temporary bonding separation methods. The separation method is not specifically limited in the present disclosure, and can be selected according to actual needs.

Subsequently, a dielectric layer may be formed on the surfaces of the first chip and the first plastic encapsulation layer away from the second chip and on the plurality of conductive posts.

Specifically, as shown in FIG. 26, the dielectric layer 2180 may be coated on the surfaces of the first chip 2110 and the first plastic encapsulation layer 2160 away from the second chip 2140 and on the plurality of conductive posts 2150. The dielectric layer 180 may be made of a material including polyimide (PI), polybenzoxazole (PBO), etc., and may be formed by a coating method including wafer spin coating, which are not specifically limited in this embodiment.

Then, the dielectric layer may be patterned, and the redistribution wiring layer may be formed on the patterned dielectric layer.

Specifically, as shown in FIG. 26, the dielectric layer 2180 may be patterned by a photolithography process, and the redistribution wiring layer 2190 may be formed on the patterned dielectric layer 2180. The redistribution wiring layer 2190 may be electrically connected to the second chip 2140 through the plurality of conductive through holes 2130 and the plurality of conductive posts 2150. The redistribution wiring layer 2190 may be formed by electroplating, sputtering, thermal evaporation, plasma enhanced chemical vapor deposition, low pressure chemical vapor deposition, atmospheric pressure chemical vapor deposition or electron cyclotron resonance chemical vapor deposition, etc., which are not specifically limited in this embodiment. The redistribution wiring layer 2190 may be made of a material including metal titanium or metal copper, which is not limited in this embodiment.

The redistribution wiring layer 2190 may be electrically connected to the first chip 2110 through the plurality of conductive through holes 2130 to lead out the signals of the first chip 2110. The redistribution layer 2190 may be electrically connected to the second chip 140 through the plurality of conductive posts 2150 to lead out the signal of the second chip 2140.

Subsequently, the redistribution wiring layer may be patterned, and solder balls may be formed on the patterned redistribution wiring layer.

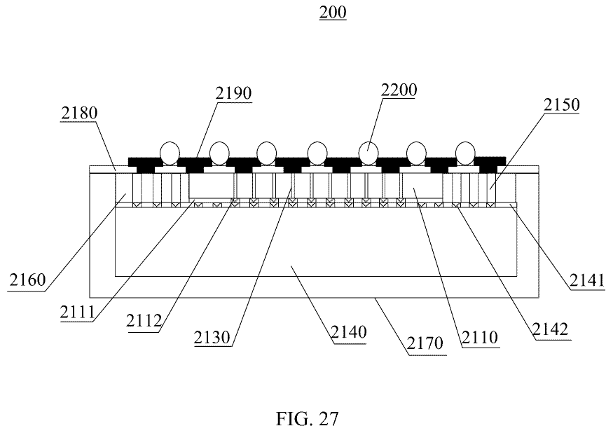

Specifically, as shown in FIG. 27, the redistribution wiring layer 2190 may be patterned by a photolithography process, and ball planting may be performed on the patterned redistribution wiring layer 190 to form a plurality of solder balls 2200. Electrically connection to the outside world may be realized through the plurality of solder balls 2200.

In the fan-out stacked chip packaging method provided by the present disclosure, the first chip may be fixed in the groove on the dummy chip, and both the first chip and the dummy chip may be provided with the plurality of conductive through holes. The second chip may be hybrid-bonded to the dummy chip and the first chip respectively, through wafer expansion technology, and then the wafer-level hybrid bonding may be performed to achieve high-density interconnection while improving production efficiency.

Further, the dummy chip may be separated from the second chip, and the plurality of conductive posts may be formed on the surface of the second chip facing the first chip and on the outer side of the first chip. The plurality of conductive posts may be used to lead out part of the signals of the second chip. The first chip may be provided with the plurality of conductive through holes, and the redistribution wiring layer may be formed on the surfaces of the first chip and the first plastic encapsulation layer away from the second chip. In the present disclosure, a traditional substrate interconnection may be replaced by the plurality of conductive through holes, the plurality of conductive posts and the fan-out redistribution wiring layer, to reduce package size.

Also, the first chip and the second chip may be bonded by using direct wafer bonding, and the thickness after bonding may be the same as that of the chip bodies, which may minimize the package height and realize ultra-thin multi-layer high-density stacked packaging.

Another embodiment of the present disclosure also provides another fan-out stacked chip packaging structure. As shown in FIG. 27, the packaging structure 200 may include a first chip 2110, a second chip 2140, a plurality of conductive posts 2150, a hybrid bonding structure (not shown in the figure), a first plastic encapsulation layer 2160, a second plastic encapsulation layer 2170, and a redistribution wiring layer 2190.

The first chip 2110 may be provided with a plurality of conductive through holes 2130. The plurality of conductive through holes 2130 may be distributed at equal intervals, and may be through-silicon vias. Through-silicon via technology may be used to realize the vertical electrical interconnection of through-silicon vias, to reduce the package height.

The second chip 2140 may be stacked and disposed on the first chip 2110 through the hybrid bonding structure.

The plurality of conductive posts 2150 may be disposed on a side of the second chip 2140 facing the first chip 2110, and on an outer side of the first chip 2110. The signals of the second chip 140 may be led out through the plurality of conductive posts 2150. A traditional substrate interconnection may be replaced by the plurality of conductive posts 2150, further reducing the package height.

The first plastic encapsulation layer 2160 may wrap the first chip 2110 and the plurality of conductive posts 2150, to protect the first chip 2110 and the plurality of conductive posts 2150.

The second plastic encapsulation layer 2170 may wrap the first chip 2110, the second chip 2140 and the first plastic encapsulation layer 2160. The second plastic encapsulation layer 2170 may protect the first chip 2110, the second chip 2140 and the first plastic encapsulation layer 2160.

The redistribution wiring layer 2190 may be disposed on the surfaces of the first chip 2110 and the first plastic encapsulation layer 2160 away from the second chip 2140. The redistribution wiring layer 2190 may be electrically connected to the second chip 2140 through the plurality of conductive through holes 2130 and the plurality of conductive posts 2150. Package size may be further reduced by replacing traditional substrate interconnects with the fan-out redistribution wiring technology. The redistribution wiring layer 2190 may be formed by electroplating, sputtering, thermal evaporation, plasma enhanced chemical vapor deposition, low pressure chemical vapor deposition, atmospheric pressure chemical vapor deposition or electron cyclotron resonance chemical vapor deposition, etc., which are not specifically limited in this embodiment. The redistribution wiring layer 2190 may be made of a material including metal titanium or metal copper, which is not limited in this embodiment.

In one embodiment, as shown in FIG. 27, the hybrid bonding structure may include a first passivation layer 2111 and first metal pads 2112 arranged on the surface of the first chip 2110 facing the second chip 2140, and a second passivation layer 2141 and second metal pads 2142 on the surface of the second chip 2140 facing the first chip 110. The first passivation layer 2111 and the second passivation layer 2141 may be bonded and connected. The first metal pads 112 and the second metal pads 2142 may be bonded and connected.

In one embodiment, as shown in FIG. 27, the package structure 200 may further include a dielectric layer 2180 and solder balls 2200. The dielectric layer 2180 may be disposed on the surfaces of the second plastic encapsulation layer 2170 and the first chip 2110 away from the second chip 2140. A redistribution wiring layer 2190 may be disposed on the dielectric layer 2180, and the solder balls 2200 may be disposed on the redistribution wiring layer 2190. The package structure may be electrically connected to the outside through the solder balls 2200.

The first passivation layer 2111 and the second passivation layer 2141 may be silicon dioxide layers, or may be made of other materials that can play a passivation role. The first metal pads 2112 and the second metal pads 2142 may be made of a material including metal copper, or other metal materials, which is not specifically limited in this embodiment. The dielectric layer 2180 may be made of a material including polyimide (PI) or polybenzoxazole (PBO), etc., and may be formed by a coating method including wafer spin coating, which is not specifically limited in this embodiment. The redistribution wiring layer 2190 may be made of a material including metal titanium, metal copper, or other metal materials, which is not specifically limited in this embodiment.

In the fan-out stacked chip packaging structure provided by the present disclosure, the second chip may be connected to the first chip through the hybrid bonding structure, which realizes high-density interconnection while improving production efficiency and reducing the packaging height to the greatest extent. The plurality of conductive posts may be arranged on the side of the second chip facing the first chip, and on the outer side of the first chip. A portion of the signals of the second chip may be led out through the plurality of conductive posts. The redistribution wiring layer may be arranged on the surfaces of the first chip and the first plastic encapsulation layer away from the second chip. Compared with the substrate interconnection, the plurality of conductive posts, the plurality of conductive through holes, and the redistribution wiring layers may be used to further reduce the packaging height and realize high-density and ultra-thin packaging.

The present disclosure also provides another fan-out stacked chip packaging method S300.

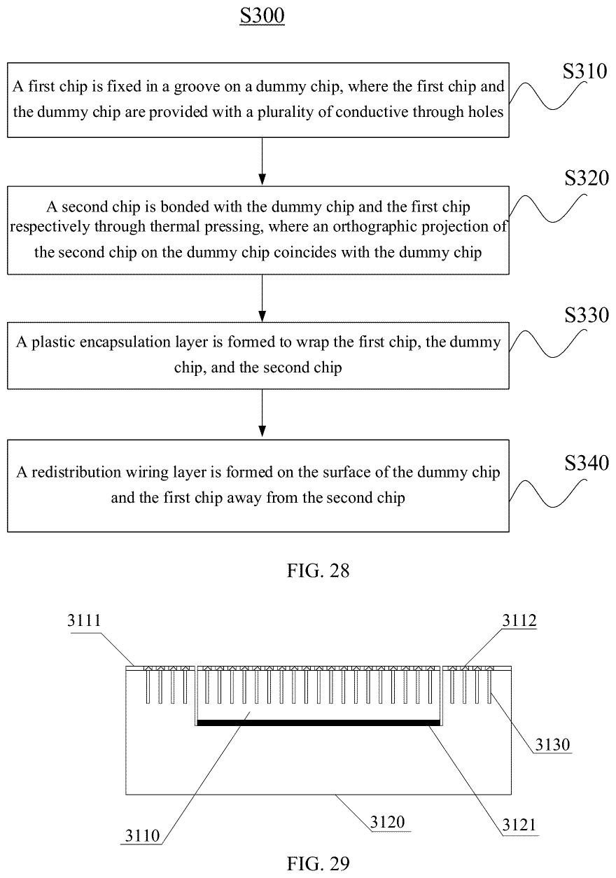

As shown in FIG. 28, the fan-out stacked chip packaging method S300 may include S310 to S340.

In S310, a first chip may be fixed in a groove on a dummy chip. The first chip and the dummy chip may both be provided with a plurality of conductive through holes.

Specifically, as shown in FIG. 29, a back side of the first chip 3110 may be fixed in the groove on the dummy chip 3120 by patch adhesive 3121, and a surface of the first chip 3110 may be flush with a surface of the dummy chip 3120. By making the surface of the first chip 3110 flush with the surface of the dummy chip 3120, they may be able to be better bonded with a second chip 3140 by thermal press. The plurality of conductive through holes 3130 may be disposed on a front surface of the first chip 3110 and a front surface of the dummy chip 3120, and the plurality of conductive through holes 3130 may be distributed at equal intervals. The plurality of conductive through holes 3130 may be through-silicon vias. The through-silicon vias may be used to realize vertical electrical interconnection of through-silicon vias. The package height may be reduced.

In S320, the second chip may be bonded with the dummy chip and the first chip respectively through thermal pressing. An orthographic projection of the second chip on the dummy chip may coincide with the dummy chip.

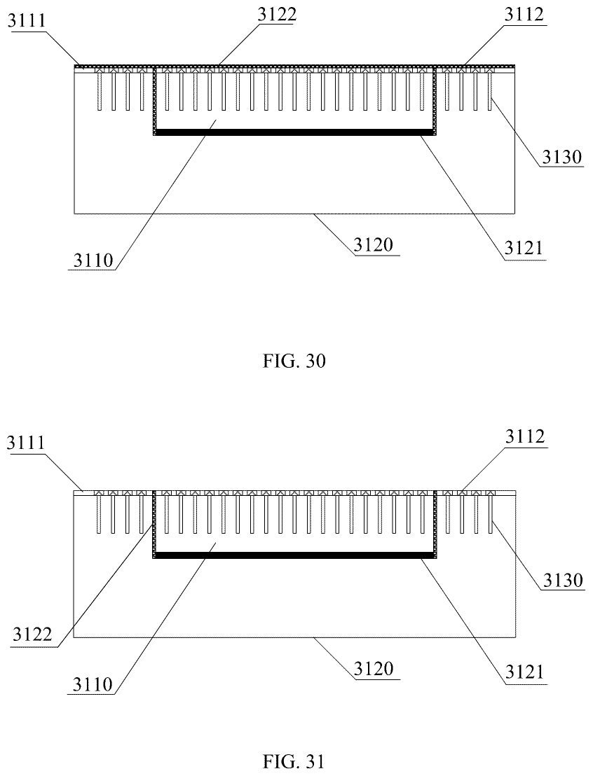

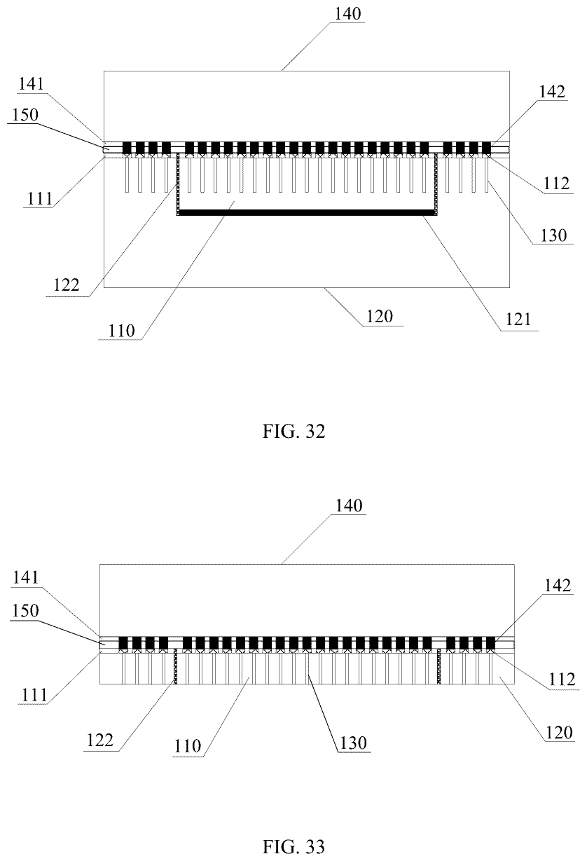

Specifically, as shown in FIG. 29, FIG. 30 and FIG. 31, a surface of the first chip 3110 and a surface of the dummy chip 3120 facing the second chip 3140 may be provided with a first passivation layer 3111 and first metal pads 3112. Each first metal pad 3112 on the first chip 3110 may correspond to one of the plurality of conductive through holes 3130 of the first chip 110, and each first metal pad 3112 on the dummy chip 3120 may correspond to one of the plurality of conductive through holes 3130 of the dummy chip 3120. As shown in FIG. 32, a surface of the second chip 3140 facing the first chip 110 may be provided with a second passivation layer 3141 and conductive bumps 3142.

In one embodiment, before bonding the second chip with the dummy chip and the first chip respectively by thermal press, the method may further include: first, forming an adhesive on the surfaces of the dummy chip and the first chip, where a portion of the adhesive may be filled into a gap between the dummy chip and the first chip; and then removing the adhesive on the surface of the dummy chip and the first chip to expose the first passivation layer and the first metal pads of the dummy chip and the first chip.

Specifically, as shown in FIG. 30, the adhesive 3122 may be formed on the surfaces of the dummy chip 3120 and the first chip 3110, and a portion of the adhesive 3122 may be filled into the gap between the dummy chip 3120 and the first chip 3110, such that the first chip 3110 may be completely fixed in the groove of the dummy chip 120.

Specifically, the surface of the adhesive 3122 may be ground and polished to remove the portion of the adhesive 3122 on the surfaces of the dummy chip 3120 and the first chip 3110, as shown in FIG. 31, to expose the first passivation layer 3111 and the first metal pads 3112 of the dummy chip 3120 and the first chip 3110.

In another embodiment, before bonding the second chip with the dummy chip and the first chip respectively by thermal press, the method may further include: forming a non-conductive adhesive layer to wrap the conductive bumps.

Specifically, as shown in FIG. 32, before the second chip 3140 is bonded to the dummy chip 3120 and the first chip 3110 respectively by thermal compress, that is, after the adhesive 3122 on the surfaces of the dummy chip 3120 and the first chip 3110 is removed to expose the first passivation layer 3111 and the first metal pads 3112 of the dummy chip 3120 and the first chip 3110, the non-conductive adhesive layer 3150 may be formed, and the non-conductive adhesive layer 3150 may wrap the conductive bumps 3142 to protect the conductive bumps 3142.

There are currently two ways of using non-conductive adhesive. In one method, the non-conductive adhesive may be made into a thin film structure to form the non-conductive adhesive layer 3150, which may be pre-coated on a surface of the second chip 3140 facing the first chip 3110 and wrap the conductive bumps 3142. Then the first metal pads 3112 of the first chip 3110 and the conductive bumps 3142 of the second chip 3140 may be soldered and connected. In another method, the non-conductive adhesive may be coated on a surface of the first chip 3110 facing the second chip 3140, to form the non-conductive adhesive layer 3150, and then the second chip 140 may be soldered and connected to the first chip 110 through the non-conductive adhesive layer 3150.

Since the non-conductive adhesive is applied before the conductive bumps 3142 are soldered, all the non-conductive adhesive on a soldering interface may need to be discharged from the soldering interface during soldering, which has extremely high requirements on the properties of the non-conductive adhesive material. The non-conductive adhesive layer formed by the non-conductive adhesive may be able to ensure the soldering effect between the first metal pads 3112 and the conductive bumps 3142.

In one embodiment, the second chip may be bonded with the dummy chip and the first chip respectively through thermal press, by bonding the metal pads and the conductive bumps through thermal press.

Specifically, as shown in FIG. 32, the conductive bumps 3142 and the metal pads 3112 may be soldered together through action of heat and pressure, to realize bonding and connection. In one embodiment, the conductive bumps 3142 may be made of a material including copper tin conductive bumps, and the metal pads 3112 may be made of a material including metal copper, which are not limited in the present disclosure.

As shown in FIG. 32, the orthographic projection of the second chip 3140 on the dummy chip 3120 may coincide with the dummy chip 3120. That is, the size of the second chip 3140 may be consistent with the size of the dummy chip 3120. The first chip 3110 and the second chip 3140 of two different sizes may be adjusted to the same size by using a dummy chip to expand the functional area of the first chip 3110. The first chip and the second chip of two different sizes may be adjusted to the same size through wafer expansion technology, and then wafer-level hybrid bonding may be performed to achieve high-density interconnection while improving production efficiency.

In S330, a plastic encapsulation layer may be formed to wrap the first chip, the dummy chip, and the second chip.

First, the bonded first chip and the dummy chip may be thinned to expose the plurality of conductive through holes of the first chip and the dummy chip.

Specifically, as shown in FIG. 33, the backsides of the bonded first chip 3110 and the dummy chip 3120 may be thinned to expose the plurality of conductive through holes 3130 of the first chip 3110 and the dummy chip 3120, that is, the through-silicon vias. A residual thickness of the first chip 3110 and the dummy chip 3120 after thinning may be less than 40 μm. By thinning the backsides of the first chip 3110 and the dummy chip 3120, the plurality of conductive through holes 3130 may be exposed for electrical connection, further reducing the package height.

Subsequently, the surface of the thinned first chip and the dummy chip facing away from the second chip may be fixed on a temporary carrier, and then the plastic encapsulation layer may be formed.

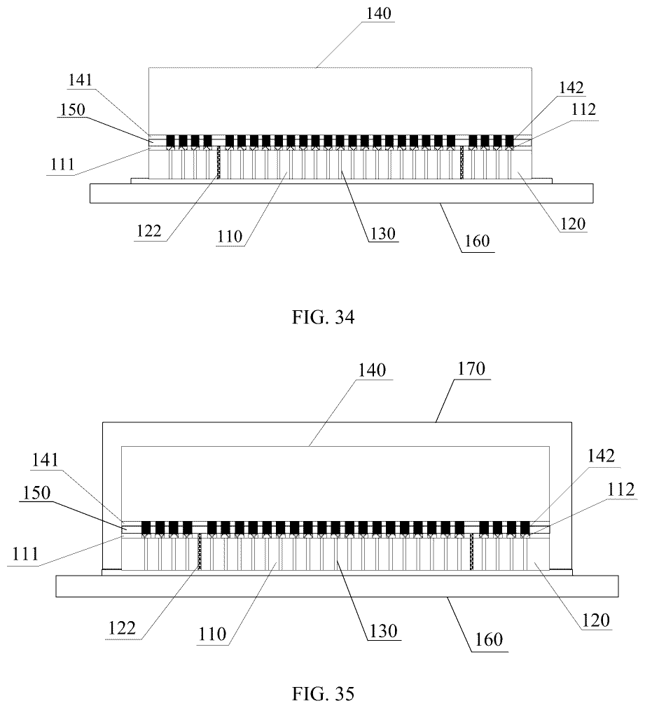

Specifically, the above packaging process may be used to package a plurality of first chips 3110, a plurality of dummy chips 3120 and a plurality of second chips 3140 at the same time. After thinning, a plurality of chip assemblies may be cut to form a plurality of independent chip assemblies shown in FIG. 33 and then the following packaging process may be performed on each of the plurality of independent chip assemblies. As shown in FIG. 34, the surface of the thinned first chip 3110 and dummy chip 3120 away from the second chip 3140 may be fixed on the temporary carrier 3160. That is, the backsides of the first chip 3110 and the dummy chip 3120 may be used as a contact surface. According to the final packaging size, they may be attached to the temporary carrier 3160 with temporary bonding glue one by one, and then packaged to form the plastic encapsulation layer 3170 as shown in FIG. 35. The plastic encapsulation layer 3170 may wrap the first chip 3110, the dummy chip 3120, and second chip 3140. The plastic encapsulation layer may be formed by a plastic encapsulation method including film vacuum lamination or traditional plastic sealing process, which is not specifically limited in the present disclosure.

In S340, a redistribution wiring layer may be formed on the surface of the dummy chip and the first chip away from the second chip, and the redistribution wiring layer may be electrically connected to the first chip through the plurality of conductive through holes.

In one embodiment, the redistribution wiring layer may be formed on the surface of the dummy chip and the first chip away from the second chip by: separating the first chip and the dummy chip from the temporary carrier; forming a dielectric layer on surfaces of the plastic encapsulation layer, the dummy chip and the first chip away from the second chip; and patterning the dielectric layer and forming the redistribution wiring layer on the patterned dielectric layer.

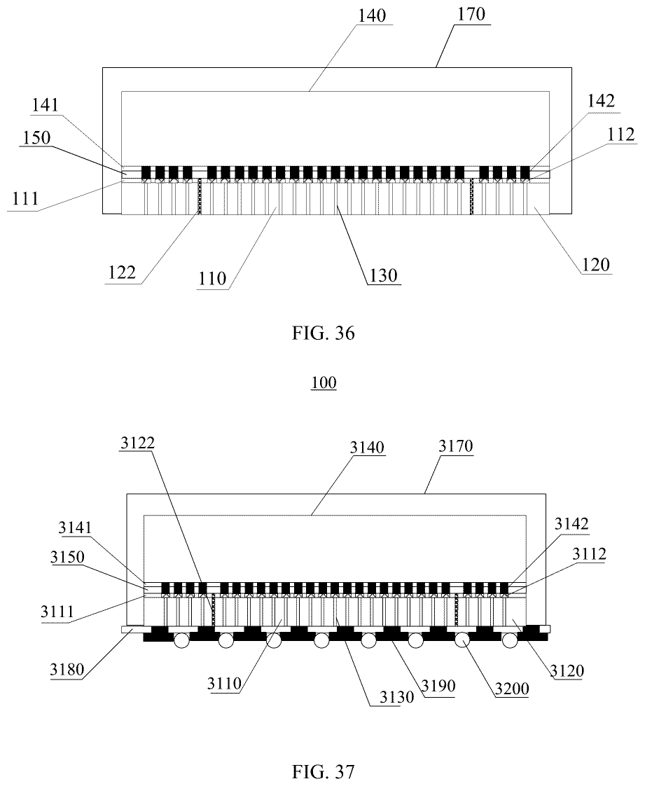

Specifically, as shown in FIG. 36, the first chip 3110 and the dummy chip 3120 may be separated from the temporary carrier 3160. That is, the temporary carrier 3160 may be removed. The first chip 3110 and the dummy chip 3120 may be separated from the temporary carrier 3160 by a separation method including thermal separation, laser separation, ultraviolet light separation, mechanical separation or other methods. These methods are currently commonly used temporary bonding separation methods. The separation method is not specifically limited in the present disclosure, and may be selected according to actual needs.

As shown in FIG. 37, the dielectric layer 3180 may be coated on the surfaces of the plastic encapsulation layer 3170, the dummy chip 3120 and the first chip 3110 away from the second chip 3149. That is, the dielectric layer 3180 may be formed on the backside of the plastic encapsulation layer 3170, the thinned first chip 3110 and the dummy chip 3120. The dielectric layer 3180 may be made of a material including polyimide (PI), polybenzoxazole (PBO), etc., and may be formed by a coating method including wafer spin coating, which are not specifically limited in the present disclosure.

As shown in FIG. 37, the dielectric layer 3180 may be patterned by a photolithography process, and the redistribution wiring layer 3190 may be formed on the patterned dielectric layer 3180. The redistribution wiring layer 3190 may be electrically connected to the first chip 3110 through the plurality of conductive through holes 3130. The redistribution wiring layer 3190 may be formed by a method including electroplating or sputtering, which is not specifically limited in the present disclosure. The redistribution wiring layer 190 may be made of a material including metal titanium or metal copper, which is not limited in the present disclosure.

Subsequently, the redistribution wiring layer may be patterned, and solder balls may be formed on the patterned redistribution wiring layer.

Specifically, as shown in FIG. 37, the redistribution wiring layer 3190 may be patterned by a photolithography process, and ball planting may be performed on the patterned redistribution wiring layer 3190 to form a plurality of solder balls 3200. Electrically connection to the outside world may be realized through the plurality of solder balls 3200.

In the fan-out stacked chip packaging method provided by the present disclosure, the first chip may be fixed in the groove on the dummy chip, and both the first chip and the dummy chip may be provided with the plurality of conductive through holes. The second chip may be bonded to the dummy chip and the first chip respectively by thermal press. The dummy chip may be used to adjust the first chip and the second chip with different sizes to a same size, and then wafer thermal press bonding may be performed, to achieve high-density interconnection while improving production efficiency. Also, conductive through hole technology and fan-out rewiring technology may be used to replace existing substrate interconnection, to reduce package size. Further, since the first chip and the second chip may be directly bonded through wafer bonding, the thickness after bonding may be the same as that of the chip body, which minimizes the package height and achieves ultra-thinning multilayer high-density stacked packaging.

The present disclosure also provides another fan-out stacked chip packaging structure. As shown in FIG. 37, in one embodiment, the fan-out stacked chip packaging structure 300 may include a dummy chip 3120, a first chip 3110, a second chip 3140, a thermal press bonding structure (not shown in the figure), a plastic encapsulation layer 3170, and a redistribution wiring layer 3180. The dummy chip 3120 may be provided with a groove, and the first chip 3110 may be disposed in the groove. The first chip 3110 and the dummy chip 3120 may be both provided with a plurality of conductive through holes 3130, and the plurality of conductive through holes 3130 may be through-silicon vias. The through-silicon vias may be used to realize the vertical electrical interconnection, which reduces the package height.

The second chip 3140 may be stacked on the first chip 3110 and the dummy chip 3120. The second chip 3140 may be connected to the dummy chip 3120 and the first chip 3110 by the thermal press bonding structure respectively. An orthographic projection of the second chip on the dummy chip 3120 may coincide with the dummy chip 3120. That is, the size of the second chip 3140 may be the same as that of the dummy chip 3120. The first chip 3110 and the second chip 3140 of two different sizes may be adjusted to the same size by the dummy chip 3120, thereby expanding the function area of the first chip 3110.

The plastic encapsulation layer 3170 may wrap the first chip 3110, the dummy chip 3120 and the second chip 3140 to protect the first chip 3110, the dummy chip 3120 and the second chip 3154.

The redistribution wiring layer 3190 may be disposed on the surfaces of the dummy chip 3120 and the first chip 3110 away from the second chip 3140, and may be electrically connected to the first chip 3110 through the plurality of conductive through holes 3130.

In one embodiment shown in FIG. 37, a first passivation layer 3111 and first metal pads 3112 may be disposed on the surfaces of the first chip 3110 and the dummy chip 3120 facing the second chip 3140, and a second passivation layer 3141 and conductive bumps 3142 may be disposed on a surface of the second chip 3140 facing the first chip 3110. The thermal press bonding structure may include the metal pads 3122 and the conductive bumps 3142. The first metal pads 3112 and the conductive bumps 3142 may be bonded by thermal press. That is, the conductive bumps 3142 and the metal pads 3112 may be soldered together through action of heat and pressure, to realize bonding and connection.

In one embodiment shown in FIG. 37, the packaging structure 300 may further include a non-conductive adhesive layer 3150 wrapping the conductive bumps 3142 to protect the conductive bumps 3142.

In one embodiment shown in FIG. 37, the packaging structure 300 may further include a dielectric layer 3180 and solder balls 3200. The dielectric layer 3180 may be disposed on the surfaces of the plastic encapsulation layer 3170, the dummy chip 3120 and the first chip 3110 away from the second chip 3140. The redistribution wiring layer 3190 may be disposed on the dielectric layer 3180 and the solder balls 3200 may be disposed on the redistribution wiring layer 3190. The solder balls 3200 may be electrically connected to the outside.

In the fan-out stacked chip packaging structure provided by the present disclosure, the first chip and the second chip of two different sizes may be adjusted to the same size by fixing the first chip in the groove of the dummy chip, and the second chip may be stacked and disposed on the first chip and the dummy chip. The second chip may be respectively connected to the dummy chip and the first chip through the thermal press bonding structure, realizing high-density interconnection while improving production efficiency. The packaging height may be reduced to the greatest extent, realizing ultra-thin packaging.

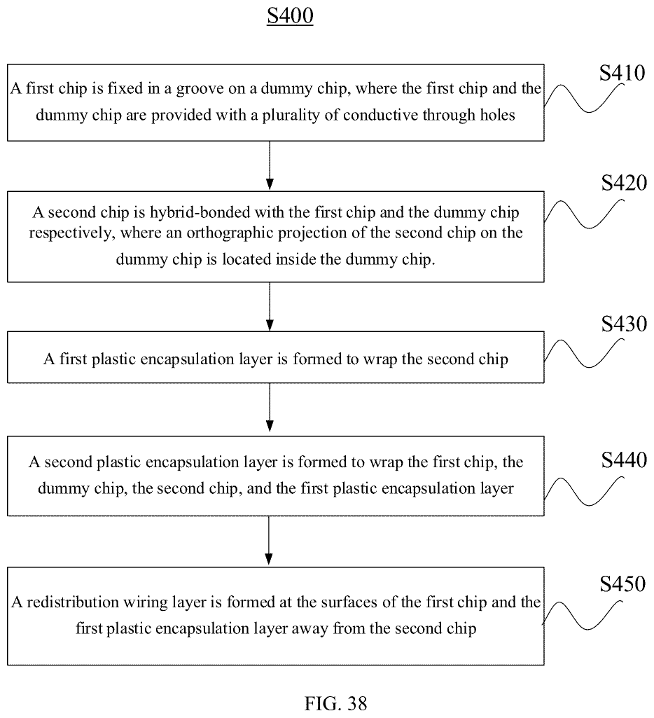

Another embodiment of the present disclosure provides another fan-out stacked chip packaging method S400. As shown in FIG. 38, the method S400 may include S410 to S460.

In S410, a first chip may be fixed in a groove on a dummy chip. The first chip and the dummy chip may be both provided with a plurality of conductive through holes.

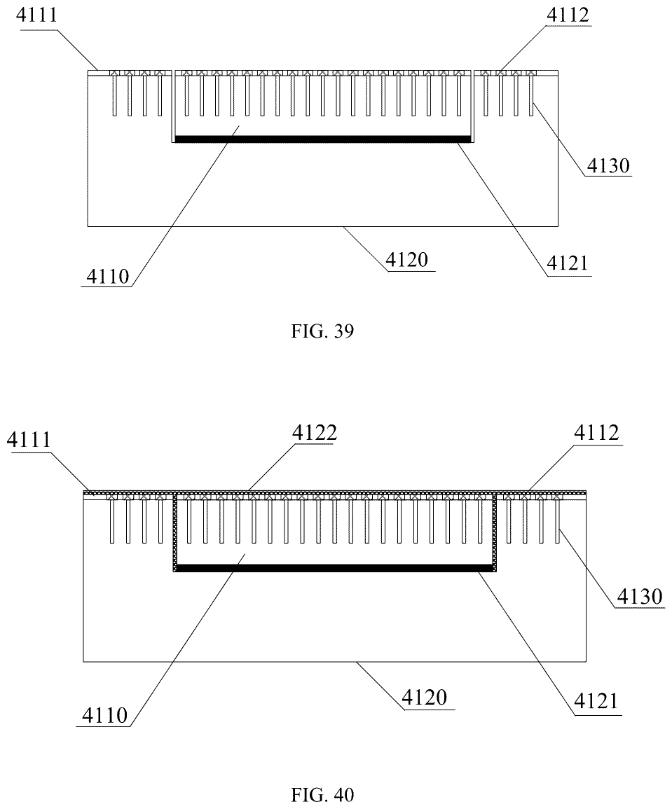

Specifically, as shown in FIG. 39, a back side of the first chip 4110 may be fixed in the groove on the dummy chip 4120 by adhesive 4121. The surface of the first chip 4110 may flush with the surface of the dummy chip 4120. By making the surface of the first chip 4110 flush with the surface of the dummy chip 4120, they may be able to be better hybrid-bonded with a second chip 4140. The dummy chip 4120 may expand a chip functional area of the first chip 4110. The front surfaces of the first chip 4110 and the dummy chip 4120 may be both provided with the plurality of conductive through holes 4130, and the plurality of conductive through holes 4130 may be distributed at equal intervals. The plurality of conductive through holes may be through-silicon vias. Through-silicon via technology may be used to realize the vertical electrical interconnection of through-silicon vias, which may reduce the package height.

In S420, the second chip may be hybrid-bonded with the first chip and the dummy chip respectively. An orthographic projection of the second chip on the dummy chip may be located inside the dummy chip.

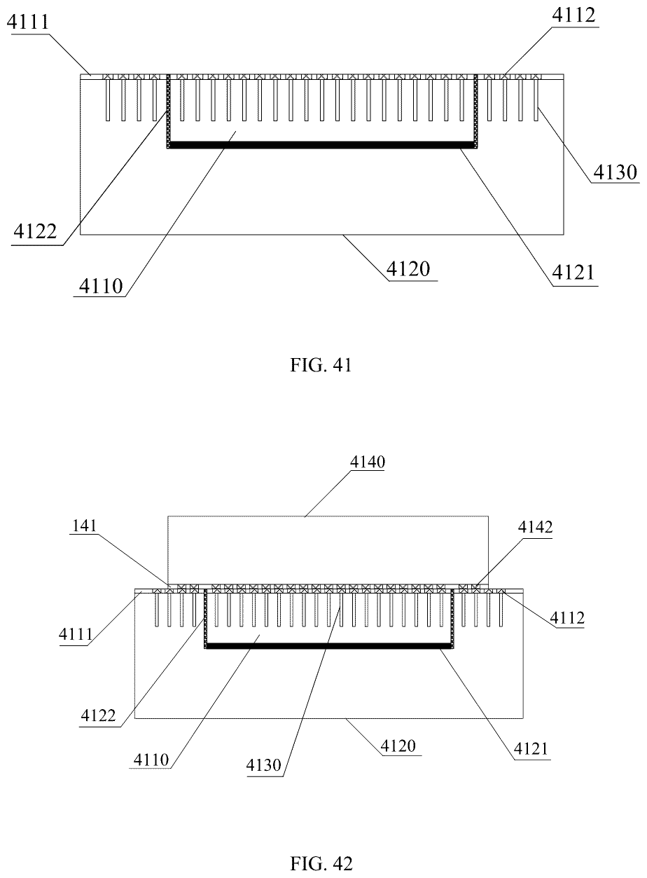

As shown in FIG. 30, FIG. 40, and FIG. 41, a surface of the first chip 4110 and a surface of the dummy chip 4120 facing the second chip 4140 may be provided with a first passivation layer 4111 and first metal pads 4112. Each first metal pad 4112 on the first chip 4110 may correspond to one of the plurality of conductive through holes 4130 of the first chip 110, and each first metal pad 4112 on the dummy chip 4120 may correspond to one of the plurality of conductive through holes 4130 of the dummy chip 4120. As shown in FIG. 42, a surface of the second chip 4140 facing the first chip 4110 may be provided with a second passivation layer 4141 and second metal pads 4142.

In one embodiment, before hybrid bonding the second chip with the dummy chip and the first chip respectively, the method may further include: first, forming an adhesive on the surfaces of the dummy chip and the first chip, where a portion of the adhesive may be filled into a gap between the dummy chip and the first chip; and then removing the adhesive on the surface of the first chip and the surface of the dummy chip, to expose the first passivation layer and the first metal pads on the first chip and the dummy chip.

Specifically, as shown in FIG. 40, the adhesive 4122 may be formed on the surfaces of the dummy chip 4120 and the first chip 4110, and a portion of the adhesive 4122 may be filled into the gap between the dummy chip 4120 and the first chip 4110. The first chip 4110 may be completely fixed in the groove of the dummy chip 4120.

Specifically, the surface of the adhesive 4122 on the first surface of the first chip 4110 may be ground and polished to remove the adhesive 4122 on the surface of the first chip 4110 and the dummy chip 4120, as shown in FIG. 41, to expose the first passivation layer 4111 and the first metal pads 4112 on the first chip 110 and the dummy chip 4120.

The second chip may be hybrid-bonded with the dummy chip and the first chip respectively by following processes.

First, the first passivation layer 4111 of the first chip 4110 and the dummy chip 4120 may be bonded with the second passivation layer 4141 of the second chip 4140. In one embodiment, the first passivation layer 4111 and the second passivation layer 4141 may be made of a material including a silicon dioxide layer, a silicon nitride layer, or other materials that play a passivation role, which is not limited in the present disclosure. Specifically, the first passivation layer 4111 and the second passivation layer 4141 may be aligned first. Then, the first passivation layer 4111 may be connected to the second passivation layer 4141 through high temperature pressure bonding.

Subsequently, the first metal pads 4112 of the first chip 4110 and the dummy chip 4120 and the second metal pads 4142 of the second chip 4140 may be bonded. In one embodiment, the first metal pads 4112 and the second metal pads 4142 may be made of a material including metal copper, or other metal materials, which are not specifically limited in this embodiment. Specifically, the first metal pads 4112 may be aligned with the second metal pads 4142, and the connection may be realized through high-temperature compression and thermal expansion of copper.

The second chip may be bonded with the first chip and the dummy chip respectively by wafer level hybrid bonding, to achieve high-density interconnection and improve producing efficiency.

As shown in FIG. 42, the orthographic projection of the second chip 4140 on the dummy chip 4120 may be located within the dummy chip 4120. That is, the size of the second chip 4140 may smaller than the size of the dummy chip 4120.

In S4130, a first plastic encapsulation layer may be formed to wrap the second chip.

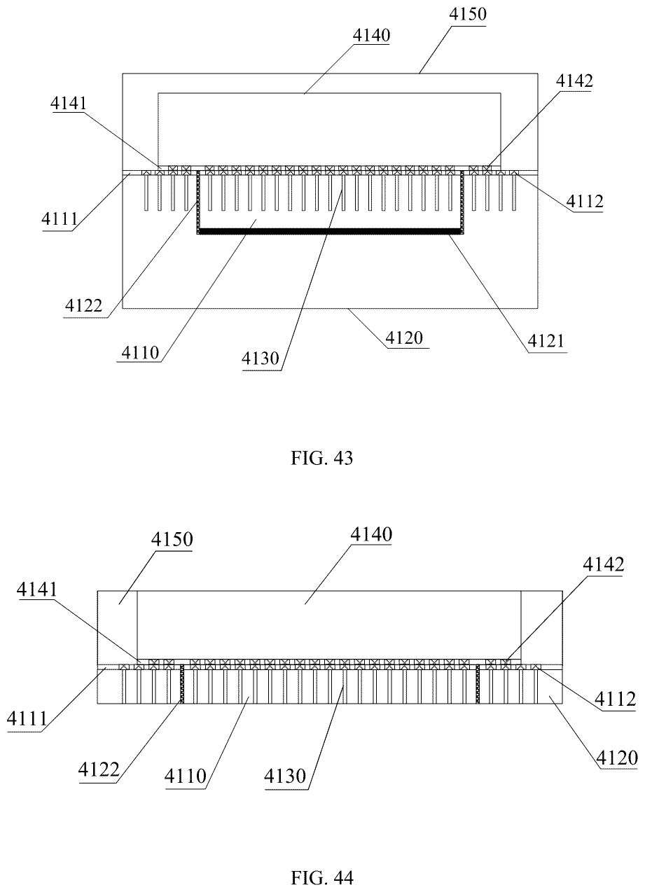

Specifically, as shown in FIG. 43, since the size of the second chip 4140 may be smaller than the size of the dummy chip 4120, the first plastic encapsulation layer 4150 may be formed on the second chip 4140, to protect the second chip 4140. Correspondingly, a size of the first plastic encapsulation layer 4150 may be same as the size of the dummy chip 4120. That is, the first plastic encapsulation layer 4150 may expand the second chip 4140. The first plastic encapsulation layer 4150 may be formed by a plastic encapsulation method including film vacuum lamination or traditional plastic sealing process, which is not specifically limited in this embodiment.

In S4140, a second plastic encapsulation layer may be formed to wrap the first chip, the dummy chip, the second chip, and the first plastic encapsulation layer.

First, the bonded first chip and the dummy chip may be thinned to expose the plurality of conductive through holes of the first chip and the dummy chip.

Specifically, as shown in FIG. 44, the backsides of the bonded first chip 4110 and the dummy chip 4120 may be thinned to expose the plurality of conductive through holes 4130 of the first chip 4110 and the dummy chip 4120, that is, the through-silicon vias. A residual thickness of the first chip 4110 and the dummy chip 4120 after thinning may be less than 40 μm. By thinning the backsides of the first chip 4110 and the dummy chip 4120, the plurality of conductive through holes 4130 may be exposed for electrical connection, further reducing the package height. In the present embodiment, the thickness of the first plastic encapsulation layer 4150 and the thickness of the second chip 4140 may be also large, and the first plastic encapsulation layer 4150 and the second chip 4140 may be also thinned.

Subsequently, the surfaces of the thinned first chip and the dummy chip facing away from the second chip may be fixed on a temporary carrier, and then the second plastic encapsulation layer may be formed.

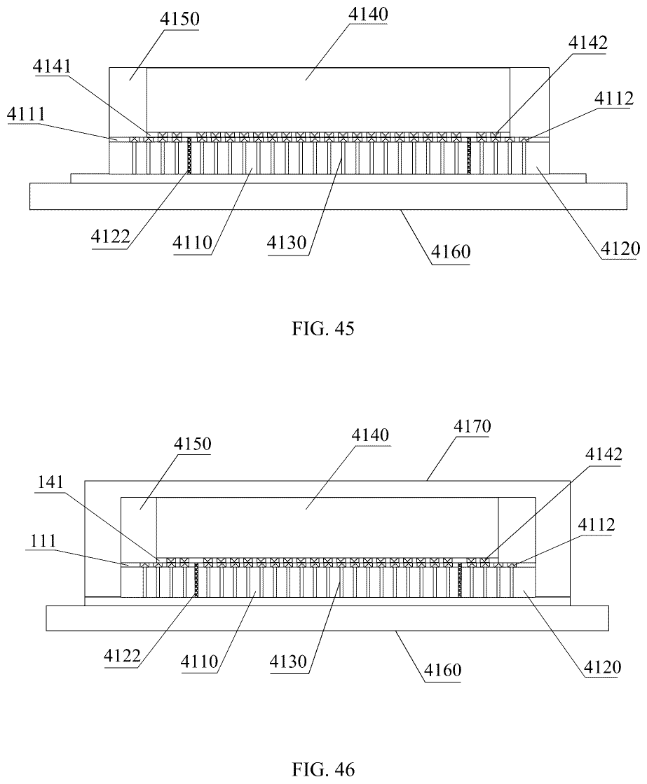

Specifically, the above packaging process may be used to package a plurality of first chips 4110, a plurality of dummy chips 4120 and a plurality of second chips 4140 at the same time. After thinning, a plurality of chip assemblies may be cut to form a plurality of independent chip assemblies shown in FIG. 44 and then the following packaging process may be performed on each of the plurality of independent chip assemblies. As shown in FIG. 45, the surface of the thinned first chip 4110 and dummy chip 4120 away from the second chip 4140 may be fixed on the temporary carrier 4160. That is, the backsides of the first chip 4110 and the dummy chip 4120 may be used as a contact surface. According to the final packaging size, they may be attached to the temporary carrier 4160 with temporary bonding glue one by one, and then packaged to form the second plastic encapsulation layer 4170 as shown in FIG. 46. The second plastic encapsulation layer 4170 may wrap the first chip 4110, the dummy chip 4120, and second chip 4140. The second plastic encapsulation layer may be formed by a plastic encapsulation method including film vacuum lamination or traditional plastic sealing process, which is not specifically limited in the present disclosure.

In S450, a redistribution wiring layer may be formed at the surfaces of the first chip and the first plastic encapsulation layer away from the second chip. The redistribution wiring layer may be electrically connected to the first chip through the plurality of conductive through holes.

In one embodiment, the redistribution wiring layer may be formed on the surfaces of the first chip and the first plastic encapsulation layer away from the second chip by the following processes.

Firstly, the first chip and the first plastic encapsulation layer may be separated from the temporary carrier.

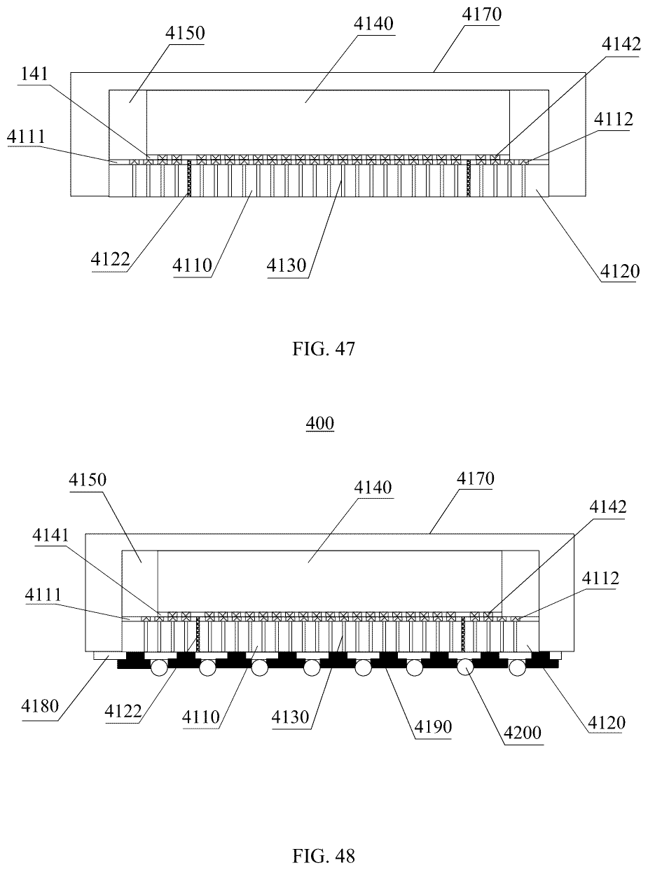

Specifically, as shown in FIG. 47, the first chip 4110 and the dummy chip 4120 may be separated from the temporary carrier 4160. That is, the temporary carrier 4160 may be removed. The first chip 4110 and the dummy chip 4120 may be separated from the temporary carrier 4160 by a separation method including thermal separation, laser separation, ultraviolet light separation, mechanical separation and other methods. These methods are currently commonly used temporary bonding separation methods. The separation method is not specifically limited in the present disclosure, and can be selected according to actual needs.

Subsequently, a dielectric layer may be formed on the surfaces of the second plastic encapsulation layer, the first chip and the dummy chip away from the second chip and on the plurality of conductive posts.

Specifically, as shown in FIG. 48, the dielectric layer 4180 may be coated on the surfaces of the first chip 4110, the second plastic encapsulation layer 4170, and the dummy chip 4120 away from the second chip 4140. That is, the dielectric layer 4180 may be formed on the backsides of the second plastic encapsulation layer 4170, the thinned first chip 4110 and the dummy chip 4120 away from the second chip 4140. The dielectric layer 180 may be made of a material including polyimide (PI), polybenzoxazole (PBO), etc., and may be formed by a coating method including wafer spin coating, which are not specifically limited in this embodiment.

Then, the dielectric layer may be patterned, and the redistribution wiring layer may be formed on the patterned dielectric layer.

Specifically, as shown in FIG. 48, the dielectric layer 4180 may be patterned by a photolithography process, and the redistribution wiring layer 4190 may be formed on the patterned dielectric layer 4180. The redistribution wiring layer 2190 may be electrically connected to the first chip 4110 through the plurality of conductive through holes 4130. The redistribution wiring layer 4190 may be formed by electroplating, sputtering, thermal evaporation, plasma enhanced chemical vapor deposition, low pressure chemical vapor deposition, atmospheric pressure chemical vapor deposition or electron cyclotron resonance chemical vapor deposition, etc., which are not specifically limited in this embodiment. The redistribution wiring layer 4190 may be made of a material including metal titanium or metal copper, which is not limited in this embodiment.

Subsequently, the redistribution wiring layer may be patterned, and solder balls may be formed on the patterned redistribution wiring layer.

Specifically, as shown in FIG. 48, the redistribution wiring layer 4190 may be patterned by a photolithography process, and ball planting may be performed on the patterned redistribution wiring layer 190 to form a plurality of solder balls 4200. Electrically connection to the outside world may be realized through the plurality of solder balls 4200.

In the fan-out stacked chip packaging method provided by the present disclosure, by using the wafer expansion technology, the dummy chip and the first plastic encapsulation layer may be used to expand the first chip and the second chip respectively. The first chip and the second chip may be bonded by wafer-level hybrid bonding, to achieve high-density interconnection while improving production efficiency. Further, a traditional substrate interconnection may be replaced by the plurality of conductive through holes, the plurality of conductive posts and the fan-out redistribution wiring layer, to reduce package size. Also, the first chip and the second chip may be bonded by using direct wafer bonding, and the thickness after bonding may be the same as that of the chip bodies, which may minimize the package height and realize ultra-thin multi-layer high-density stacked packaging.

Another embodiment of the present disclosure also provides another fan-out stacked chip packaging structure. As shown in FIG. 48, the packaging structure 400 may include a first chip 4110, a second chip 4140, a dummy chip 4120, a hybrid bonding structure (not shown in the figure), a first plastic encapsulation layer 4150, a second plastic encapsulation layer 5170, and a redistribution wiring layer 4190. The dummy chip 4120 may be provided with a groove and the first chip 4110 may be disposed in the groove. The first chip 4110 and the dummy chip 4120 may be both provided with a plurality of conductive through holes 4130. The plurality of conductive through holes 4130 may be distributed at equal intervals, and may be through-silicon vias. Through-silicon via technology may be used to realize the vertical electrical interconnection of through-silicon vias, to reduce the package height.

The second chip 4140 may be stacked and disposed on the first chip 4110 and the dummy chip 4120. The second chip 4140 may be bonded and connected to the first chip 4110 and the dummy chip 4120 through the hybrid bonding structure respectively. An orthographic projection of the second chip 4140 on the dummy chip 4120 may be located within the dummy chip 4120, that is, the size of the second chip 4140 may be smaller than the size of the dummy chip 4120.

The first plastic encapsulation layer 4150 may wrap the second chip 4140, to protect the second chip 4140. Since the size of the second chip 4140 may be smaller than the size of the dummy chip 4120, the first plastic encapsulation layer 4150 may be formed on the second chip 4140, such that the size of the first plastic encapsulation layer 4150 wrapping the second chip 4140 may be the same as the size of the dummy chip 4120.

The second plastic encapsulation layer 4170 may wrap the first chip 4110, the second chip 4140, the dummy chip 4120 and the first plastic encapsulation layer 4150. The second plastic encapsulation layer 4170 may protect the first chip 4110, the second chip 4140, the dummy chip 4120 and the first plastic encapsulation layer 4150.

The redistribution wiring layer 4190 may be disposed on the surfaces of the first chip 4110 and the dummy chip 4120 away from the second chip 4140. The redistribution wiring layer 4190 may be electrically connected to the first chip 4110 through the plurality of conductive through holes 4130.

In one embodiment, as shown in FIG. 48, the hybrid bonding structure may include a first passivation layer 4111 and first metal pads 4112 arranged on the surface of the first chip 4110 facing the second chip 4140, and a second passivation layer 4141 and second metal pads 4142 on the surface of the second chip 4140 facing the first chip 4110. The first passivation layer 4111 and the second passivation layer 4141 may be bonded and connected. The first metal pads 4112 and the second metal pads 4142 may be bonded and connected.

In one embodiment, as shown in FIG. 48, the surface of the first chip 4110 may be flush with the surface of the dummy chip 4120.

In one embodiment, as shown in FIG. 48, the package structure 400 may further include a dielectric layer 4180 and solder balls 4200. The dielectric layer 4180 may be disposed on the surfaces of the second plastic encapsulation layer 4170, the dummy chip 4120, and the first chip 4110 away from the second chip 4140. The redistribution wiring layer 4190 may be disposed on the dielectric layer 4180, and the solder balls 4200 may be disposed on the redistribution wiring layer 4190. The package structure may be electrically connected to the outside through the solder balls 4200.

In the fan-out stacked chip packaging structure provided by the present disclosure, by using the wafer expansion technology, the dummy chip and the first plastic encapsulation layer may be used to expand the first chip and the second chip respectively. The first chip and the second chip may be bonded by wafer-level hybrid bonding, to achieve high-density interconnection while improving production efficiency. Further, a traditional substrate interconnection may be replaced by the plurality of conductive through holes, the plurality of conductive posts and the fan-out redistribution wiring layer, to reduce package size. Also, the first chip and the second chip may be bonded by using direct wafer bonding, and the thickness after bonding may be the same as that of the chip bodies, which may minimize the package height and realize ultra-thin multi-layer high-density stacked packaging.

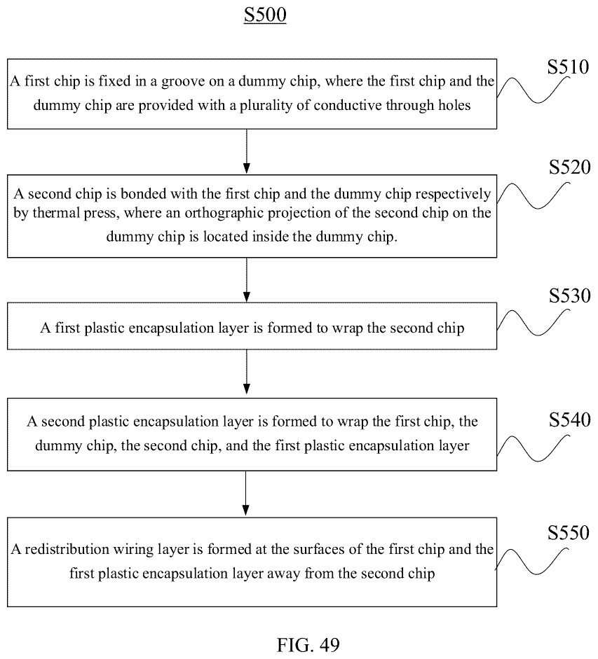

Another embodiment of the present disclosure provides another fan-out stacked chip packaging method S500. As shown in FIG. 49, the method S500 may include S510 to S550.

In S510, a first chip may be fixed in a groove on a dummy chip. The first chip and the dummy chip may be both provided with a plurality of conductive through holes.

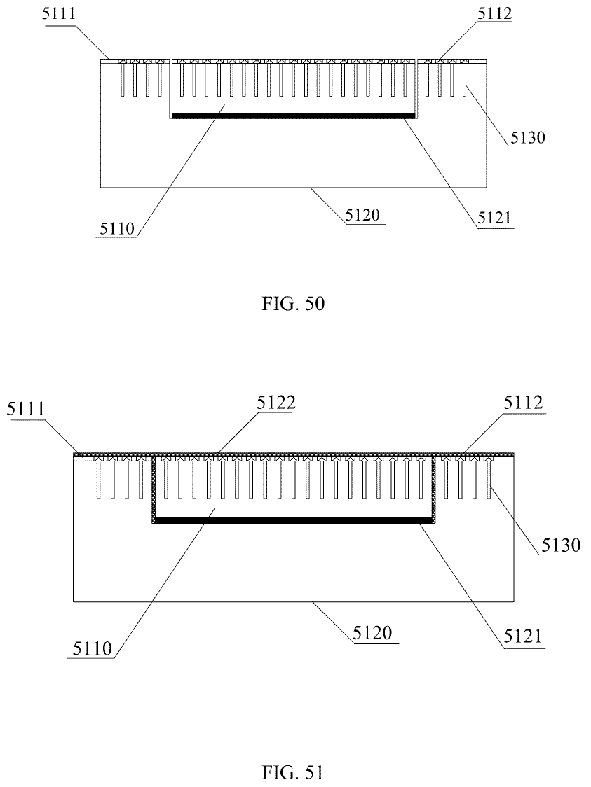

Specifically, as shown in FIG. 50, a back side of the first chip 5110 may be fixed in the groove on the dummy chip 5120 by adhesive 5121. The surface of the first chip 5110 may flush with the surface of the dummy chip 5120. By making the surface of the first chip 5110 flush with the surface of the dummy chip 5120, they may be able to be better hybrid-bonded with a second chip 5140. The dummy chip 5120 may expand a chip functional area of the first chip 5110. The front surfaces of the first chip 5110 and the dummy chip 5120 may be both provided with the plurality of conductive through holes 5130, and the plurality of conductive through holes 5130 may be distributed at equal intervals. The plurality of conductive through holes may be through-silicon vias. Through-silicon via technology may be used to realize the vertical electrical interconnection of through-silicon vias, which may reduce the package height.

In S520, the second chip may be bonded with the first chip and the dummy chip respectively by thermal press. An orthographic projection of the second chip on the dummy chip may be located inside the dummy chip.

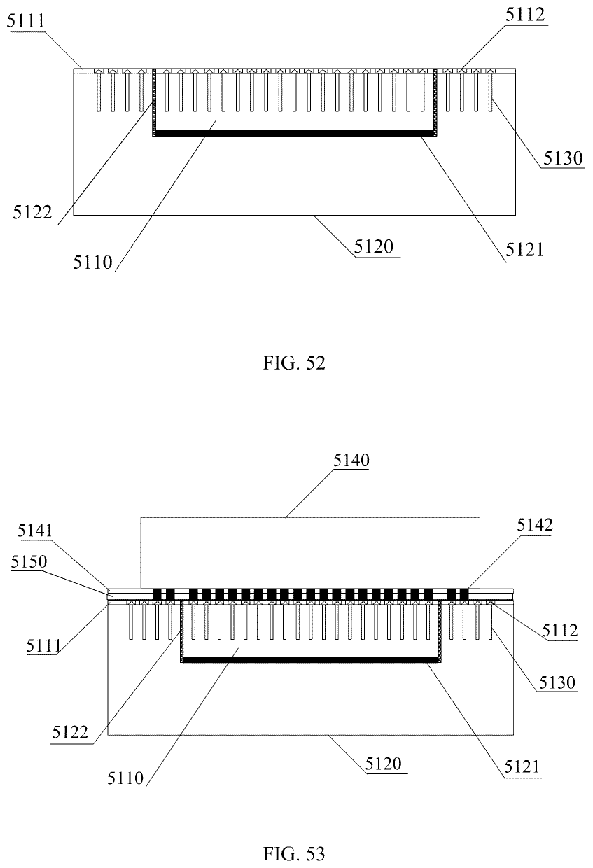

As shown in FIG. 50, FIG. 51, and FIG. 52, a surface of the first chip 5110 and a surface of the dummy chip 5120 facing the second chip 5140 may be provided with a first passivation layer 5111 and first metal pads 5112. Each first metal pad 5112 on the first chip 5110 may correspond to one of the plurality of conductive through holes 5130 of the first chip 110, and each first metal pad 5112 on the dummy chip 5120 may correspond to one of the plurality of conductive through holes 5130 of the dummy chip 5120. As shown in FIG. 42, a surface of the second chip 5140 facing the first chip 5110 may be provided with a second passivation layer 5151 and conductive bumps 5142.

In one embodiment, before bonding the second chip with the dummy chip and the first chip respectively by thermal press, the method may further include: first, forming an adhesive on the surfaces of the dummy chip and the first chip, where a portion of the adhesive may be filled into a gap between the dummy chip and the first chip; and then removing the adhesive on the surface of the first chip and the surface of the dummy chip, to expose the first passivation layer and the first metal pads on the first chip and the dummy chip.

Specifically, as shown in FIG. 51, the adhesive 5122 may be formed on the surfaces of the dummy chip 5120 and the first chip 5110, and a portion of the adhesive 5122 may be filled into the gap between the dummy chip 5120 and the first chip 5110. The first chip 5110 may be completely fixed in the groove of the dummy chip 5120.

Specifically, the surface of the adhesive 5122 on the surface of the first chip 5110 and the dummy chip 5210 may be ground and polished to remove the adhesive 5122 on the surface of the first chip 5110 and the dummy chip 5120, as shown in FIG. 52, to expose the first passivation layer 5111 and the first metal pads 5112 on the first chip 110 and the dummy chip 5120. In some other embodiments, other methods may be used to remove the adhesive 5122 on the surface of the first chip 5110 and the dummy chip 5210, which are not limited in the present disclosure.

In another embodiment, before bonding the second chip with the dummy chip and the first chip respectively by thermal press, the method may further include: forming a non-conductive adhesive layer to wrap the conductive bumps.

Specifically, as shown in FIG. 53, before the second chip 5140 is bonded to the dummy chip 5120 and the first chip 5110 respectively by thermal compress, the non-conductive adhesive layer 5150 may be formed, and the non-conductive adhesive layer 5150 may wrap the conductive bumps 5142 to protect the conductive bumps 5142.

There are currently two ways of using non-conductive adhesive. In one method, the non-conductive adhesive may be made into a thin film structure to form the non-conductive adhesive layer 5150, which may be pre-coated on a surface of the second chip 5140 facing the first chip 5110 and wrap the conductive bumps 5142. Then the first metal pads 5112 of the first chip 5110 and the conductive bumps 5142 of the second chip 5140 may be soldered and connected. In another method, the non-conductive adhesive may be coated on a surface of the first chip 5110 facing the second chip 5140, to form the non-conductive adhesive layer 5150, and then the second chip 5140 may be soldered and connected to the first chip 5110 through the non-conductive adhesive layer 5150.

Since the non-conductive adhesive is applied before the conductive bumps 5142 are soldered, all the non-conductive adhesive on a soldering interface may need to be discharged from the soldering interface during soldering, which has extremely high requirements on the properties of the non-conductive adhesive material. The non-conductive adhesive layer formed by the non-conductive adhesive may be able to ensure the soldering effect between the first metal pads 5112 and the conductive bumps 5142.

In one embodiment, the second chip may be bonded with the dummy chip and the first chip respectively through thermal press, by bonding the metal pads and the conductive bumps through thermal press.

Specifically, as shown in FIG. 53, the first metal pads 5112 of the first chip 5110 and the conductive bumps 5142 of the second chip 5140 may be bonded by actions of heat and pressure. In one embodiment, the first metal pads 5112 may be made of a material including metal copper, and the conductive bumps 5142 may be copper-tin conductive bumps, which are not limited in the present disclosure.

As shown in FIG. 53, the orthographic projection of the second chip 5140 on the dummy chip 5120 may be located within the dummy chip 5120. That is, the size of the second chip 5140 may smaller than the size of the dummy chip 5120.

In S530, a first plastic encapsulation layer may be formed to wrap the second chip.

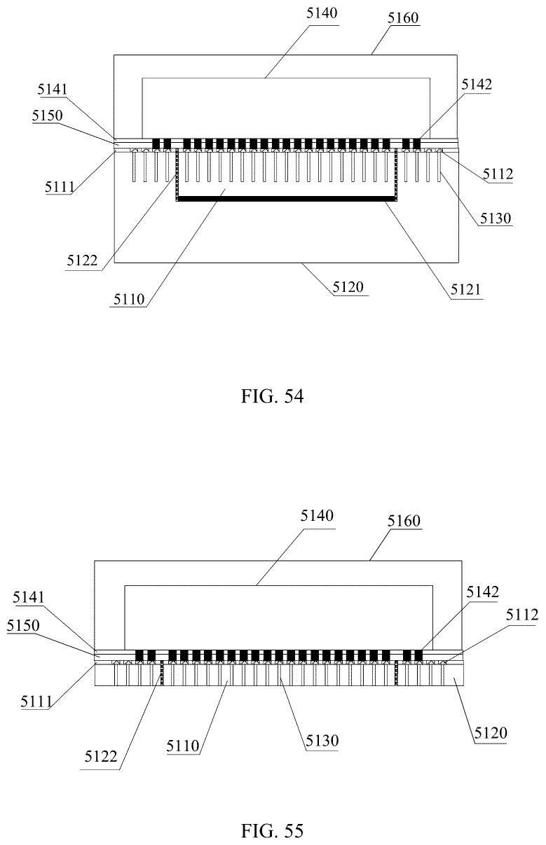

Specifically, as shown in FIG. 54, since the size of the second chip 5140 may be smaller than the size of the dummy chip 5120, the first plastic encapsulation layer 5150 may be formed on the second chip 5140, to protect the second chip 5140. Correspondingly, a size of the first plastic encapsulation layer 5150 may be same as the size of the dummy chip 5120. That is, the first plastic encapsulation layer 5150 may expand the second chip 5140. The first plastic encapsulation layer 5150 may be formed by a plastic encapsulation method including film vacuum lamination or traditional plastic sealing process, which is not specifically limited in this embodiment.

In S540, a second plastic encapsulation layer may be formed to wrap the first chip, the dummy chip, the second chip, and the first plastic encapsulation layer.

First, the bonded first chip and the dummy chip may be thinned to expose the plurality of conductive through holes of the first chip and the dummy chip.

Specifically, as shown in FIG. 55, the backsides of the bonded first chip 5110 and the dummy chip 5120 may be thinned and then the plurality of conductive through holes 5130 of the first chip 5110 and the dummy chip 5120, that is, the through-silicon vias, may be exposed by etching. A residual thickness of the first chip 5110 and the dummy chip 5120 after thinning may be less than 40 μm. By thinning the backsides of the first chip 5110 and the dummy chip 5120, the plurality of conductive through holes 5130 may be exposed for electrical connection, further reducing the package height. In the present embodiment, the thickness of the first plastic encapsulation layer 5150 and the thickness of the second chip 5140 may be also large, and the first plastic encapsulation layer 5150 and the second chip 5140 may be also thinned.

Subsequently, the surfaces of the thinned first chip and the dummy chip facing away from the second chip may be fixed on a temporary carrier, and then the second plastic encapsulation layer may be formed.

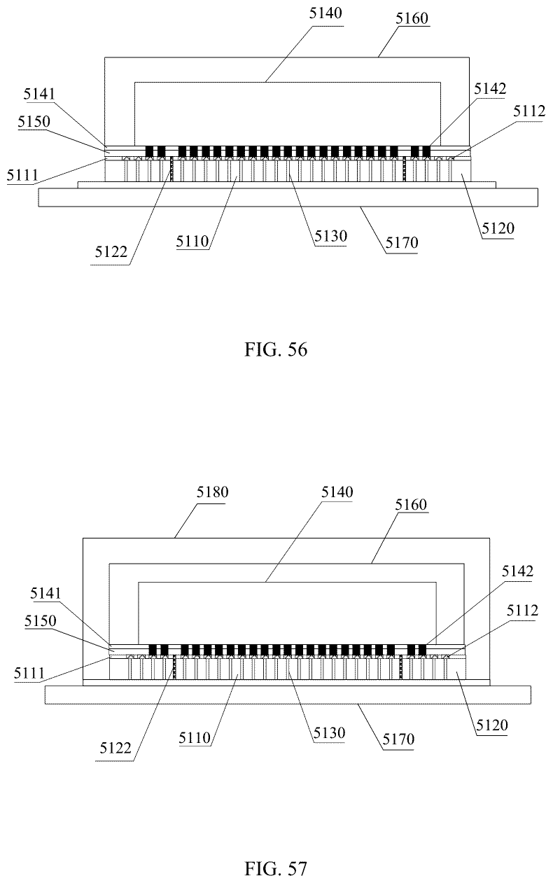

Specifically, the above packaging process may be used to packaging a plurality of first chips 5110, a plurality of dummy chips 5120 and a plurality of second chips 5140 at the same time. After thinning, a plurality of chip assemblies may be cut to form a plurality of independent chip assemblies shown in FIG. 55 and then the following packaging process may be performed on each of the plurality of independent chip assemblies. As shown in FIG. 56, the surface of the thinned first chip 5110 and dummy chip 5120 away from the second chip 5140 may be fixed on the temporary carrier 5170. That is, the backsides of the first chip 5110 and the dummy chip 5120 may be used as a contact surface. According to the final packaging size, they may be attached to the temporary carrier 5170 with temporary bonding glue one by one, and then packaged to form the second plastic encapsulation layer 5180 as shown in FIG. 57. The second plastic encapsulation layer 5180 may wrap the first chip 5110, the dummy chip 5120, the first plastic encapsulation layer 5160, and second chip 5140. The second plastic encapsulation layer may be formed by a plastic encapsulation method including film vacuum lamination or traditional plastic sealing process, which is not specifically limited in the present disclosure.

In S550, a redistribution wiring layer may be formed at the surfaces of the first chip and the dummy chip away from the second chip. The redistribution wiring layer may be electrically connected to the first chip through the plurality of conductive through holes.

In one embodiment, the redistribution wiring layer may be formed on the surfaces of the first chip and the dummy chip away from the second chip by the following processes.

Firstly, the first chip and the dummy chip may be separated from the temporary carrier.

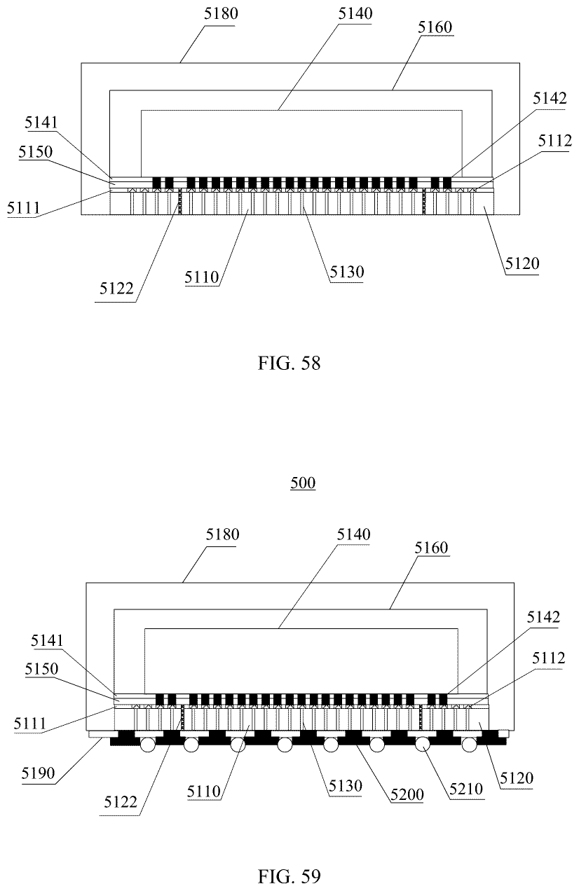

Specifically, as shown in FIG. 58, the first chip 5110 and the dummy chip 5120 may be separated from the temporary carrier 5170. That is, the temporary carrier 5170 may be removed. The first chip 5110 and the dummy chip 5120 may be separated from the temporary carrier 5160 by a separation method including thermal separation, laser separation, ultraviolet light separation, mechanical separation and other methods. These methods are currently commonly used temporary bonding separation methods. The separation method is not specifically limited in the present disclosure, and can be selected according to actual needs.

Subsequently, a dielectric layer may be formed on the surfaces of the second plastic encapsulation layer, the first chip and the dummy chip away from the second chip.

Specifically, as shown in FIG. 59, the dielectric layer 5190 may be coated on the surfaces of the first chip 5110, the second plastic encapsulation layer 5180, and the dummy chip 5120 away from the second chip 5140. That is, the dielectric layer 5190 may be formed on the backsides of the second plastic encapsulation layer 5180, the thinned first chip 5110 and the dummy chip 5120 away from the second chip 5140. The dielectric layer 5190 may be made of a material including polyimide (PI), polybenzoxazole (PBO), etc., and may be formed by a coating method including wafer spin coating, which are not specifically limited in this embodiment.

Then, the dielectric layer may be patterned, and the redistribution wiring layer may be formed on the patterned dielectric layer.

Specifically, as shown in FIG. 59, the dielectric layer 5190 may be patterned by a photolithography process, and the redistribution wiring layer 5200 may be formed on the patterned dielectric layer 5190. The redistribution wiring layer 5200 may be electrically connected to the first chip 5110 through the plurality of conductive through holes 5130. The redistribution wiring layer 5200 may be formed by electroplating, sputtering, thermal evaporation, plasma enhanced chemical vapor deposition, low pressure chemical vapor deposition, atmospheric pressure chemical vapor deposition or electron cyclotron resonance chemical vapor deposition, etc., which are not specifically limited in this embodiment. The redistribution wiring layer 5200 may be made of a material including metal titanium or metal copper, which is not limited in this embodiment.

Subsequently, the redistribution wiring layer may be patterned, and solder balls may be formed on the patterned redistribution wiring layer.

Specifically, as shown in FIG. 59, the redistribution wiring layer 5200 may be patterned by a photolithography process, and ball planting may be performed on the patterned redistribution wiring layer 5200 to form a plurality of solder balls 5210. Electrically connection to the outside world may be realized through the plurality of solder balls 5210.

In the fan-out stacked chip packaging method provided by the present disclosure, by using the wafer expansion technology, the dummy chip and the first plastic encapsulation layer may be used to expand the first chip and the second chip respectively. The first chip and the second chip may be bonded by thermal press, to achieve high-density interconnection while improving production efficiency. Further, a traditional substrate interconnection may be replaced by the plurality of conductive through holes, the plurality of conductive posts and the fan-out redistribution wiring layer, to reduce package size. Also, the first chip and the second chip may be bonded by using direct wafer bonding, and the thickness after bonding may be the same as that of the chip bodies, which may minimize the package height and realize ultra-thin multi-layer high-density stacked packaging.

Another embodiment of the present disclosure also provides another fan-out stacked chip packaging structure 500. As shown in FIG. 59, the packaging structure 500 may include a first chip 5110, a second chip 5140, a dummy chip 5120, a thermal-press bonding structure (not shown in the figure), a first plastic encapsulation layer 5150, a second plastic encapsulation layer 5180, and a redistribution wiring layer 5200. The dummy chip 5120 may be provided with a groove and the first chip 5110 may be disposed in the groove. The first chip 5110 and the dummy chip 5120 may be both provided with a plurality of conductive through holes 5130. The plurality of conductive through holes 5130 may be distributed at equal intervals, and may be through-silicon vias. Through-silicon via technology may be used to realize the vertical electrical interconnection of through-silicon vias, to reduce the package height.

The second chip 5140 may be stacked and disposed on the first chip 5110 and the dummy chip 5120. The second chip 5140 may be bonded and connected to the first chip 5110 and the dummy chip 5120 through the thermal-press bonding structure respectively. An orthographic projection of the second chip 5140 on the dummy chip 5120 may be located within the dummy chip 5120, that is, the size of the second chip 5140 may be smaller than the size of the dummy chip 5120. The dummy chip 5120 may be used to expand the first chip 4110 and the second chip 5140 with different sizes, and then they may be bonded through wafer-level thermal press bonding, to achieve high-density interconnection and improve the producing efficiency.

The first plastic encapsulation layer 5160 may wrap the second chip 5140, to protect the second chip 5140.

The second plastic encapsulation layer 5180 may wrap the first chip 5110, the second chip 5140, the dummy chip 5120 and the first plastic encapsulation layer 5160. The second plastic encapsulation layer 5170 may protect the first chip 5110, the second chip 5140, the dummy chip 5120 and the first plastic encapsulation layer 51560.

The redistribution wiring layer 5200 may be disposed on the surfaces of the first chip 5110 and the dummy chip 5120 away from the second chip 5140. The redistribution wiring layer 5200 may be electrically connected to the first chip 5110 through the plurality of conductive through holes 5130.

In one embodiment, as shown in FIG. 59, a first passivation layer 5111 and first metal pads 5112 may be arranged on the surface of the first chip 5110 facing the second chip 5140, and a second passivation layer 5141 and conductive bumps 5142 may be arranged on the surface of the second chip 5140 facing the first chip 5110. The thermal-press bonding structure may include the first metal pads 5112 and the conductive bumps 5142. The first metal pads 5112 and the conductive bumps 5142 may be bonded and connected through thermal press. That is, the first metal pads 5112 and the conductive bumps 5142 may be soldered for connection through the actions of heat and pressure.

In one embodiment, as shown in FIG. 59, the packaging structure 500 may further include a non-conductive adhesive layer 5150. The non-conductive adhesive layer 5150 may wrap the conductive bumps 5142 to protect the conductive bumps 5142.

In one embodiment, as shown in FIG. 59, the package structure 500 may further include a dielectric layer 5190 and solder balls 5210. The dielectric layer 5190 may be disposed on the surfaces of the second plastic encapsulation layer 5180, the dummy chip 5120, and the first chip 5110 away from the second chip 5140. The redistribution wiring layer 5200 may be disposed on the dielectric layer 5190, and the solder balls 5210 may be disposed on the redistribution wiring layer 5200. The package structure may be electrically connected to the outside through the solder balls 5210.

In the fan-out stacked chip packaging structure provided by the present disclosure, by using the wafer expansion technology, the dummy chip and the first plastic encapsulation layer may be used to expand the first chip and the second chip respectively. The first chip and the second chip may be bonded by wafer-level thermal-press bonding, to achieve high-density interconnection while improving production efficiency. Further, a traditional substrate interconnection may be replaced by the plurality of conductive through holes, the plurality of conductive posts and the fan-out redistribution wiring layer, to reduce package size. Also, the first chip and the second chip may be bonded by using direct wafer bonding, and the thickness after bonding may be the same as that of the chip bodies, which may minimize the package height and realize ultra-thin multi-layer high-density stacked packaging.

The embodiments disclosed herein are exemplary only. Other applications, advantages, alternations, modifications, or equivalents to the disclosed embodiments are obvious to those skilled in the art and are intended to be encompassed within the scope of the present disclosure.

What is claimed is:

1. A fan-out packaging method, comprising:
fixing a first chip in a groove of a dummy chip, wherein the first chip and the dummy chip are provided with a plurality of conductive through holes;
bonding the second chip with the dummy chip and the first chip respectively;
forming a plastic encapsulation layer to wrap the first chip, the dummy chip and the second chip; and
forming a redistribution wiring layer on surfaces of the dummy chip and the first chip away from the second chip, wherein the redistribution layer is electrically connected to the first chip through the plurality of conductive through holes.

2. The method according to claim 1, wherein:
an orthographic projection of the second chip on the dummy chip coincides with the dummy chip.

3. The method according to claim 1, wherein:
the second chip is bonded with the dummy chip and the first chip respectively by hybrid bonding;
a first passivation layer and first metal pads are provided on surfaces of the first chip and the dummy chip facing the second chip;
a second passivation layer and second metal pads are provided on a surface of the second chip facing the first chip; and
bonding the second chip with the dummy chip and the first chip respectively includes:
bonding the first passivation layer of the first chip and the dummy chip with the second passivation layer of the second chip; and
bonding the first metal pads of the first chip and the dummy chip with the second metal pads of the second chip.

4. The method according to claim 3, before bonding the second chip with the dummy chip and the first chip respectively, further including:
forming an adhesive on the surfaces of the dummy chip and the first chip, wherein a portion of the adhesive is filled into a gap between the dummy chip and the first chip; and
removing the adhesive on the surfaces of the dummy chip and the first chip to expose the first passivation layer and the first metal pads of the dummy chip and the first chip.

5. The method according to claim 1, wherein forming the plastic encapsulation layer includes:
thinning the bonded first chip and the dummy chip to expose the plurality of conductive through holes of the first chip and the dummy chip; and
fixing the surfaces of the thinned first chip and the dummy chip away from the second chip on a temporary carrier, and then forming the plastic encapsulation layer.

6. The method according to claim 5, forming the redistribution wiring layer on the surfaces of the dummy chip and the first chip away from the second chip includes:
separating the first chip and the dummy chip from the temporary carrier;
forming a dielectric layer on surfaces of the plastic encapsulation layer, the dummy chip and the first chip away from the second chip;
patterning the dielectric layer and forming the redistribution wiring layer on the patterned dielectric layer; and
patterning the redistribution wiring layer and forming solder balls on the patterned redistribution wiring layer.

7. The method according to claim 1, wherein:
a surface of the first chip is flush with a surface of the dummy chip.

8. The method according to claim 1, wherein:
the plurality of conductive through holes are through-silicon vias.

9. The method according to claim 1, wherein:
the second chip is bonded with the dummy chip and the first chip respectively by thermal press;
a first passivation layer and first metal pads are provided on surfaces of the first chip and the dummy chip facing the second chip;
a second passivation layer and conductive bumps are provided on a surface of the second chip facing the first chip; and
bonding the second chip with the dummy chip and the first chip respectively includes:
bonding the first metal pads with the conductive bumps through thermal press.

10. The method according to claim 9, before bonding the second chip with the dummy chip and the first chip respectively further including:
forming a non-conductive adhesive layer to wrap the conductive bumps.

11. The method according to claim 1, wherein:
an orthographic projection of the second chip on the dummy chip is located within the dummy chip.

12. The method according to claim 11, before forming the plastic encapsulation layer, further including:
forming a first plastic encapsulation layer to wrap the second chip.

13. The method according to claim 11, wherein:
when forming the plastic encapsulation layer to wrap the first chip, the dummy chip and the second chip, the plastic encapsulation layer also wraps the first plastic encapsulation layer.

14. The method according to claim 11, wherein:
the second chip is bonded with the dummy chip and the first chip respectively by hybrid bonding;
a first passivation layer and first metal pads are provided on surfaces of the first chip and the dummy chip facing the second chip;
a second passivation layer and second metal pads are provided on a surface of the second chip facing the first chip; and
bonding the second chip with the dummy chip and the first chip respectively includes:
bonding the first passivation layer of the first chip and the dummy chip with the second passivation layer of the second chip; and
bonding the first metal pads of the first chip and the dummy chip with the second metal pads of the second chip.

15. The method according to claim 11, wherein:
the second chip is bonded with the dummy chip and the first chip respectively by thermal press;
a first passivation layer and first metal pads are provided on surfaces of the first chip and the dummy chip facing the second chip;
a second passivation layer and conductive bumps are provided on a surface of the second chip facing the first chip; and
bonding the second chip with the dummy chip and the first chip respectively includes:
bonding the first metal pads with the conductive bumps through thermal press.

16. The method according to claim 15, before bonding the second chip with the dummy chip and the first chip respectively further including:
forming a non-conductive adhesive layer to wrap the conductive bumps.

17. A fan-out packaging structure, comprising a dummy chip, a first chip, a second chip, a bonding structure, a plastic encapsulation layer, and a redistribution wiring layer, wherein:
the dummy chip includes a groove;
the first chip is disposed in the groove;
the first chip and the dummy chip are both provided with a plurality of conductive through holes;
the second chip is stacked on the first chip and the dummy chip;
the second chip is bonded and connected to the dummy chip and the first chip respectively through the bonding structure;
the plastic encapsulation layer wraps the first chip, the dummy chip, and the second chip;
the redistribution wiring layer is disposed on surfaces of the dummy chip and the first chip away from the second chip, wherein the redistribution layer is electrically connected to the first chip through the plurality of conductive through holes.

18. The structure according to claim 17, further including a dielectric layer and solder balls, wherein:
the dielectric layer is disposed on surfaces of the plastic encapsulation layer, the dummy chip and the first chip away from the second chip;
the redistribution wiring layer is disposed on the patterned dielectric layer; and
the solder balls is disposed on the redistribution wiring layer.

19. The structure according to claim 17, wherein:
the bonding structure is a hybrid bonding structure;
a first passivation layer and first metal pads are provided on surfaces of the first chip and the dummy chip facing the second chip;
a second passivation layer and second metal pads are provided on a surface of the second chip facing the first chip;
the first passivation layer of the first chip and the dummy chip is bonded with the second passivation layer of the second chip; and
the first metal pads of the first chip and the dummy chip are bonded with the second metal pads of the second chip.

20. The structure according to claim 17, wherein:
the bonding structure is a thermal-press bonding structure;
a first passivation layer and first metal pads are provided on surfaces of the first chip and the dummy chip facing the second chip;
a second passivation layer and conductive bumps are provided on a surface of the second chip facing the first chip; and
the first metal pads are bonded with the conductive bumps through thermal press.
